(19) United States
(12) Patent Application Publication
(10) Pub. No.: US 2021/0149304 A1
(43) Pub. Date: May 20, 2021

(54) PHOTOSENSITIVE RESIN COMPOSITION, CURED FILM, ELEMENT COMPRISING CURED FILM, ORGANIC EL DISPLAY DEVICE COMPRISING CURED FILM, METHOD FOR PRODUCING CURED FILM, AND METHOD FOR PRODUCING ORGANIC EL DISPLAY DEVICE

(71) Applicant: TORAY INDUSTRIES, INC., Tokyo (JP)

(72) Inventors: Satoshi KAMEMOTO, Otsu-shi (JP); Yuta SHUTO, Otsu-shi (JP); Kazuto MIYOSHI, Otsu-shi (JP)

(73) Assignee: TORAY INDUSTRIES, INC., Tokyo (JP)

(21) Appl. No.: 16/638,560

(22) PCT Filed: Sep. 18, 2018
(86) PCT No.: PCT/JP2018/034377

§ 371 Date: Feb. 12, 2020

(30) Foreign Application Priority Data
Sep. 26, 2017 (JP) 2017-184502

(51) Int. Cl. G03F 7/038; G03F 7/004; G03F 7/039; C08G 73/10; G03F 7/00; H01L 27/32; H01L 51/00; H01L 51/56

(52) U.S. Cl. CPC G03F 7/0387; G03F 7/0045; G03F 7/0392; C08G 73/1071; H01L 2227/323; H01L 27/3246; H01L 51/0018; H01L 51/56; G03F 7/0007

(57) ABSTRACT

A photosensitive resin composition including: an alkali-soluble resin (A); a photo acid generator (B); a thermal cross-linking agent (C); a phenolic antioxidant (D); and a compound (E₂) having a phenolic hydroxyl group indicating an acid dissociation constant pKa of 6.0 to 9.5 at 25° C.; or a photosensitive resin composition including: an alkali-soluble resin (A); a photo acid generator (B); a thermal cross-linking agent (C); a phenolic antioxidant (D); and a compound (E) having a phenolic hydroxyl group other than (D); wherein the compound (E) having a phenolic hydroxyl group other than (D) contains a compound (E₁) having an electron-withdrawing group and a phenolic hydroxyl group in the molecule. Provided is a photosensitive resin composition whose cured film has high bending resistance even after a reliability test, and also has excellent chemical resistance.

### TECHNICAL FIELD

The present invention relates to a photosensitive resin composition and a cured film using the composition, an element including a cured film, an organic EL display device including a cured film, a method of producing a cured film, and a method of producing an organic EL display device.

### BACKGROUND ART

For display devices having a thin display, such as smartphones, tablet PCs, and televisions, a number of products using an organic electroluminescence (hereinafter referred to as “organic EL”) display device have been developed.

In general, an organic EL display device includes a driving circuit, a planarization layer, a first electrode, an insulation layer, an emitting layer, and a second electrode on a substrate. Light can be emitted by application of a voltage or current between the first electrode and the second electrode, which are disposed such that they face each other. As materials for the planarization layer and materials for the insulation layer, photosensitive resin compositions that can be patterned by ultraviolet irradiation are generally used.

Since the reliabilities required for organic EL display devices are increasing year by year, materials for the planarization layer and materials for the insulation layer are also required to be capable of maintaining high film physical properties even after a reliability test under accelerated conditions such as high temperature, high humidity, and/or light irradiation.

Furthermore, especially in recent years, flexible organic EL display devices formed on resin film substrates have been widely developed. A flexible organic EL display device has a structure containing a bendable portion and/or a portion fixed in a bent state (hereinafter referred to as bending area), and a bending stress is applied to the planarization layer and the insulation layer in the bending area. In flexible organic EL display devices containing such a bending area, high bending resistance is required for materials of the planarization layer and materials of the insulation layer.

### PRIOR ART DOCUMENTS

### Patent Documents

Photosensitive resin compositions using a polyimide resin or a polybenzoxazole resin have high heat resistance of the resin, and produce only a small amount of gas components from the cured film. These compositions are therefore preferably used from the viewpoint of producing highly reliable organic EL display devices (see, for example, Patent Document 1). Further, for example, photosensitive resin compositions using a polyimide precursor in which a flexible long-chain aliphatic group is introduced to a resin backbone for improvement of the bending resistance (see, for example, Patent Document 2) have been proposed.

### [Patent Document 1] JP 2002-91343 A

### [Patent Document 2] WO 2011-059089

### SUMMARY OF THE INVENTION

### Problems to be Solved by the Invention

As described above, the reliabilities required for organic EL display devices are increasing year by year. For example, in cases where the photosensitive resin composition described in Patent Document 1 is used for a material of a planarization layer and a material of an insulation layer, film physical properties cannot be maintained after a reliability test under accelerated conditions such as high temperature, high humidity, and/or light irradiation, which is problematic.

In the technique of Patent Document 2, a flexible long-chain group is introduced. In this technique, the bending resistance immediately after processing can be improved, but film physical properties largely decrease in a reliability test, and the chemical resistance also decreases, so that the technique has practical problems.

In view of this, an object of the present invention is to provide a photosensitive resin composition whose cured film has high bending resistance even after a reliability test, and also has excellent chemical resistance; and an organic EL display device including the cured film of the photosensitive resin composition.

### Means for Solving the Problems

In order to solve the above problems, the photosensitive resin composition of the present invention has one of the following configurations RC₁ and RC₂. That is,

RC₁: a photosensitive resin composition including: an alkali-soluble resin (A); a photo acid generator (B); a thermal cross-linking agent (C); a phenolic antioxidant (D); and a compound (E₂) having a phenolic hydroxyl group indicating an acid dissociation constant pKa of 6.0 to 9.5 at 25° C.; or

RC₂: a photosensitive resin composition including: an alkali-soluble resin (A); a photo acid generator (B); a thermal cross-linking agent (C); a phenolic antioxidant (D); and a compound (E) having a phenolic hydroxyl group other than (D); wherein the compound (E) having a phenolic hydroxyl group other than (D) contains a compound (E₁) having an electron-withdrawing group and a phenolic hydroxyl group in the molecule.

In order to solve the above problems, the cured film of the present invention has the following configuration. That is,

a cured film including a cured product of the photosensitive resin composition.

In order to solve the above problems, the element including the cured film of the present invention has the following configuration. That is,

an element including the cured film.

In order to solve the above problems, the organic EL display device including the cured film of the present invention has the following configuration. That is,

an organic EL display device including the cured film.

In order to solve the above problems, the electronic component of the present invention has the following configuration. That is,

an electronic component including the cured film, the cured film being disposed as an interlayer insulation film between redistributions.

In order to solve the above problems, the method of producing a cured film of the present invention has the following configuration. That is,

a method of producing a cured film, the method including the steps of:

(1) applying the photosensitive resin composition to a substrate to form a photosensitive resin film;

(2) drying the photosensitive resin film;

(3) exposing the dried photosensitive resin film through a photomask;

(4) developing the exposed photosensitive resin film; and

(5) heat-treating the developed photosensitive resin film.

In order to solve the above problems, the method of producing an organic EL display device of the present invention has the following configuration. That is,

a method of producing an organic EL display device, the method including the step of forming a cured film by the method of producing a cured film.

In the photosensitive resin composition RC₁ of the present invention, the phenolic antioxidant (D) preferably has a phenolic hydroxyl group indicating an acid dissociation constant pKa of 10.1 to 13.0 at 25° C.

In the photosensitive resin composition RC₁ of the present invention, the mass ratio between the content of the phenolic antioxidant (D) and the content of the compound (E₂) having a phenolic hydroxyl group indicating an acid dissociation constant pKa of 6.0 to 9.5 at 25° C. (E₂/D) is preferably 2 to 20.

In the photosensitive resin composition RC₂ of the present invention, the mass ratio between the content of the phenolic antioxidant (D) and the content of the compound (E₁) having an electron-withdrawing group and a phenolic hydroxyl group in the molecule (E₁/D) is preferably 2 to 20.

In each of the photosensitive resin compositions RC₁ and RC₂ of the present invention, the alkali-soluble resin (A) preferably contains a polyimide, polyimide precursor, polybenzoxazole precursor, and/or copolymer thereof.

In each of the photosensitive resin compositions RC₁ and RC₂ of the present invention, the phenolic antioxidant (D) preferably contains a hindered phenol antioxidant.

Each of the photosensitive resin compositions RC₁ and RC₂ of the present invention is preferably used for formation of an insulation film of an organic EL display device including a bendable portion and/or a portion fixed in a bent state.

In each of the photosensitive resin compositions RC₁ and RC₂ of the present invention, the thermal cross-linking agent (C) preferably contains a thermal cross-linking agent having a phenolic hydroxyl group, and also having a methylol group and/or an alkoxymethyl group at both ortho positions of the phenolic hydroxyl group.

Each of the photosensitive resin compositions RC₁ and RC₂ of the present invention preferably further contains a coloring agent (F).

In each of the photosensitive resin compositions RC₁ and RC₂ of the present invention, the photosensitive resin composition preferably has a sheet shape.

In the organic EL display device of the present invention, at least part of a portion including the cured film of the organic EL display device preferably includes a bendable portion and/or a portion fixed in a bent state, the bendable portion and/or the portion fixed in a bent state having a curvature radius within the range of 0.1 mm to 5 mm.

### Effect of the Invention

With the photosensitive resin composition of the present invention, a photosensitive resin composition whose cured film has high bending resistance even after a reliability test, and also has excellent chemical resistance, can be provided. By using the cured film of the photosensitive resin composition, a highly reliable organic EL display device having high bending resistance even after a reliability test can be provided.

### BRIEF DESCRIPTION OF THE DRAWINGS

FIG. 1 is a cross-sectional view of a TFT substrate in which a planarization layer and an insulation layer are formed.

### MODE FOR CARRYING OUT THE INVENTION

Embodiments of the present invention are described below in detail.

The photosensitive resin composition of the present invention is a photosensitive resin composition including: an alkali-soluble resin (A); a photo acid generator (B); a thermal cross-linking agent (C); a phenolic antioxidant (D); and a compound (E₂) having a phenolic hydroxyl group indicating an acid dissociation constant pKa of 6.0 to 9.5 at 25° C.; or a photosensitive resin composition including: an alkali-soluble resin (A); a photo acid generator (B); a cross-linking agent (C); a phenolic antioxidant (D); and a compound (E) having a phenolic hydroxyl group other than (D); wherein the compound (E) having a phenolic hydroxyl group other than (D) contains a compound (E₁) having an electron-withdrawing group and a phenolic hydroxyl group in the molecule.

The photosensitive resin composition of the present invention contains an alkali-soluble resin (A). The alkali solubility in the present invention means that, when a solution of the resin in γ-butyrolactone is applied onto a silicon wafer, and prebaking is carried out at 120° C. for 4 minutes to form a prebaked film having a film thickness of 10 μm±0.5 μm, followed by immersing the prebaked film in 2.38% by mass aqueous tetramethylammonium hydroxide solution at 23±1° C. for 1 minute and then rinsing the film with pure water, the dissolution rate as determined from reduction of the film thickness is not less than 50 nm/minute.

The alkali-soluble resin (A) is not limited as long as it has the alkali solubility, and examples of the alkali-soluble resin (A) include polyimides, polyimide precursors, polybenzoxazole precursors, polyaminoamides, polyamides, polymers containing radically polymerizable monomers, siloxane resins, cardo resins, and phenol resins. Two or more of these alkali-soluble resins may be used in combination. Among the alkali-soluble resins, those having excellent heat resistance, showing less outgassing, and having excellent film physical properties in terms of elongation and the like are preferred. More specifically, the alkali-soluble resin (A) is preferably a polyimide, polyimide precursor, polybenzoxazole precursor, and/or copolymer thereof.

In the present invention, the alkali-soluble resin selected from polyimides, polyimide precursors, and polybenzoxazole precursors, or a copolymer thereof, which can be used as the alkali-soluble resin (A), preferably has an acidic group in a structural unit and/or at an end of the backbone in the resin so as to give the alkali solubility. Examples of the acidic group include a carboxyl group, phenolic hydroxyl group, sulfonate group, and thiol group. Further, the alkali-soluble resin or the copolymer thereof preferably contains a fluorine atom. In this case, water repellency can be given to the interface between the film and the base material during development with an aqueous alkaline solution, and therefore infiltration of the aqueous alkaline solution into the interface can be suppressed. The content of the fluorine atom in the alkali-soluble resin or the copolymer is preferably not less than 5% by mass from the viewpoint of effectively preventing infiltration of the aqueous alkaline solution into the interface, and preferably not more than 20% by mass from the viewpoint of solubility in the aqueous alkaline solution.

The polyimide preferably contains a structural unit represented by the following General Formula (1), and the polyimide precursor and the polybenzoxazole precursor preferably contain a structural unit represented by the following General Formula (2). Two or more of kinds of these structural units may be contained, or a resin produced by copolymerizing structural units represented by General Formula (1) with structural units represented by General Formula (2) may be used.

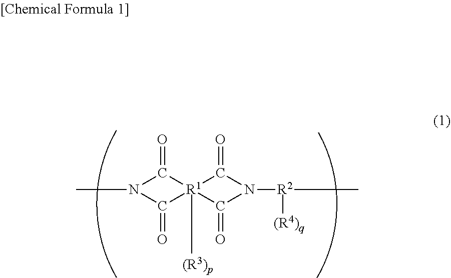

In General Formula (1), R¹ represents a tetravalent to decavalent organic group, and R² represents a divalent to octavalent organic group. R³ and R⁴ each represent a phenolic hydroxyl group, carboxy group, sulfonate group, or thiol group. Each of R³ and R⁴ may be either a single kind of groups, or may be a combination of different kinds of groups. p and q each represent an integer of 0 to 6.

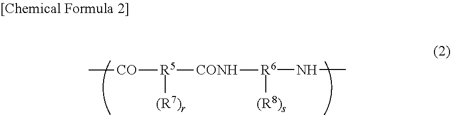

In General Formula (2), R⁵ represents a divalent to octavalent organic group, and R⁶ represents a divalent to octavalent organic group. R⁷ and R⁸ each represent a phenolic hydroxyl group, sulfonate group, thiol group, or COOR⁹. Each of R⁷ and R⁸ may be either a single kind of groups, or may be a combination of different kinds of groups. R⁹ represents a hydrogen atom or a monovalent C₁-C₂₀ hydrocarbon group. r and s each represent an integer of 0 to 6, with the proviso that r+s>0.

The alkali-soluble resin selected from polyimides, polyimide precursors, and polybenzoxazole precursors, and the copolymer thereof, preferably contain 5 to 100,000 structural units represented by General Formula (1) and/or (2). In addition to the structural units represented by General Formula (1) and/or (2), other structural units may be contained. In this case, the structural units represented by General Formula (1) and/or (2) are preferably contained at not less than 50 mol % with respect to the total number of structural units.

In the General Formula (1), R¹—(R³)ₚ represents a residue of a dianhydride. R¹ represents a tetravalent to decavalent organic group, especially preferably a C₅-C₄₀ organic group containing an aromatic ring or an alicyclic group.

Specific examples of the dianhydride include aromatic tetracarboxylic dianhydrides such as pyromellitic dianhydride, 3,3′,4,4′-biphenyltetracarboxylic dianhydride, 2,3,3′,4′-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 2,2-bis(3,4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl)ether dianhydride, 1,2,5,6-naphthalenetetracarboxylic dianhydride, 9,9-bis(3,4-dicarboxyphenyl)fluorenic dianhydride, 9,9-bis {4-(3,4-dicarboxyphenoxy)phenyl}fluorenic dianhydride, 2,3,6,7-naphthalenetetracarboxylic dianhydride, 2,3,5,6-pyridinetetracarboxylic dianhydride, 3,4,9,10-perylenetetracarboxylic dianhydride, 2,2-bis(3,4-dicarboxyphenyl)hexafluoropropane dianhydride, and dianhydrides having the structures shown below; and aliphatic tetracarboxylic dianhydrides such as butane tetracarboxylic dianhydride and 1,2,3,4-cyclopentanetetracarboxylic dianhydride. Two or more of these may be used.

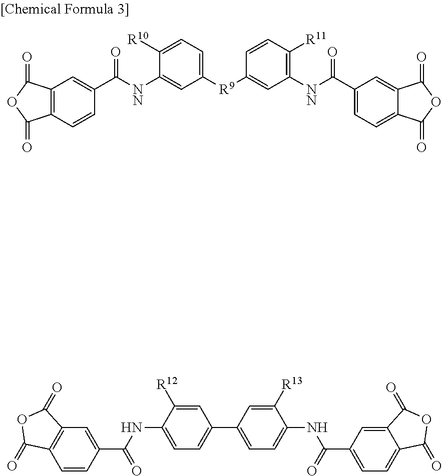

R⁹ represents an oxygen atom, C(CF₃)₂, or C(CH₃)₂. R¹⁰, R¹¹, R¹², and R¹³ each represent a hydrogen atom or a hydroxyl group.

In General Formula (2), R⁵—(R⁷)ᵣ represents an acid residue. R⁵ represents a divalent to octavalent organic group, especially preferably a C₅-C₄₀ organic group containing an aromatic ring or an alicyclic group.

Examples of the acid component include dicarboxylic acids such as terephthalic acid, isophthalic acid, diphenyl ether dicarboxylic acid, bis(carboxyphenyl)hexafluoropropane, biphenyldicarboxylic acid, benzophenone dicarboxylic acid, and triphenyldicarboxylic acid; tricarboxylic acids such as trimellitic acid, trimesic acid, diphenyl ether tricarboxylic acid, and biphenyltricarboxylic acid; and tetracarboxylic acids such as aromatic tetracarboxylic acids, for example, pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2′,3,3′-benzophenonetetracarboxylic acid, 2,2-bis(3,4-dicarboxyphenyl)hexafluoropropane, 2,2-bis(2,3-dicarboxyphenyl)hexafluoropropane, 1,1-bis(3,4-dicarboxyphenyl)ethane, 1,1-bis(2,3-dicarboxyphenyl)ethane, bis(3,4-dicarboxyphenyl)methane, bis(2,3-dicarboxyphenyl)methane, bis(3,4-dicarboxyphenyl)ether, 1,2,5,6-naphthalenetetracarboxylic acid, 2,3,6,7-naphthalenetetracarboxylic acid, 2,3,5,6-pyridinetetracarboxylic acid, 3,4,9,10-perylenetetracarboxylic acid, and those having the structures shown below, and aliphatic tetracarboxylic acids, for example, butane tetracarboxylic acid and 1,2,3,4-cyclopentanetetracarboxylic acid. Two or more of these may be used.

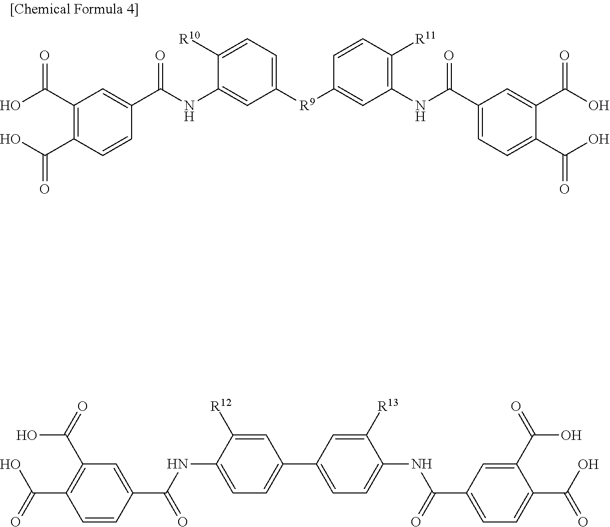

R⁹ represents an oxygen atom, C(CF₃)₂, or C(CH₃)₂. R¹⁰, R¹¹, R¹², and R¹³ each represent a hydrogen atom or a hydroxyl group.

Among these, in the tricarboxylic acids and the tetracarboxylic acids, one or two carboxyl groups correspond to the group R⁷ in General Formula (2). One to four hydrogen atoms in each of the above-exemplified dicarboxylic acids, tricarboxylic acids, and tetracarboxylic acids are more preferably substituted with the group R⁷ in General Formula (2), preferably a phenolic hydroxyl group(s). Each of these acids may be used as it is, or as an anhydride or an active ester.

R²—(R⁴)_{q} in the General Formula (1) and R⁶—(R⁸)ₛ in the General Formula (2) each represent a diamine residue. R² and R⁸ each represent a divalent to octavalent organic group, especially preferably a C₅-C₄₀ organic group containing an aromatic ring or an alicyclic group.

Specific examples of the diamine include 3,4′-diaminodiphenyl ether, 4,4′-diaminodiphenyl ether, 3,4′-diaminodiphenylmethane, 4,4′-diaminodiphenylmethane, 1,4-bis(4-aminophenoxy)benzene, benzidine, m-phenylenediamine, p-phenylenediamine, 1,5-naphthalenediamine, 2,6-naphthalenediamine, bis(4-aminophenoxy)biphenyl, bis{4-(4-aminophenoxy)phenyl}ether, 1,4-bis(4-aminophenoxy)benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, 2,2′-di(trifluoromethyl)-4,4′-diaminobiphenyl, 9,9-bis(4-aminophenyl)fluorene, compounds produced by substituting at least part of the hydrogen atoms of their aromatic rings with an alkyl group(s) and/or a halogen atom(s), aliphatic cyclohexyldiamine, methylenebis cyclohexylamine, and diamines having the structures shown below. Two or more of these may be used.

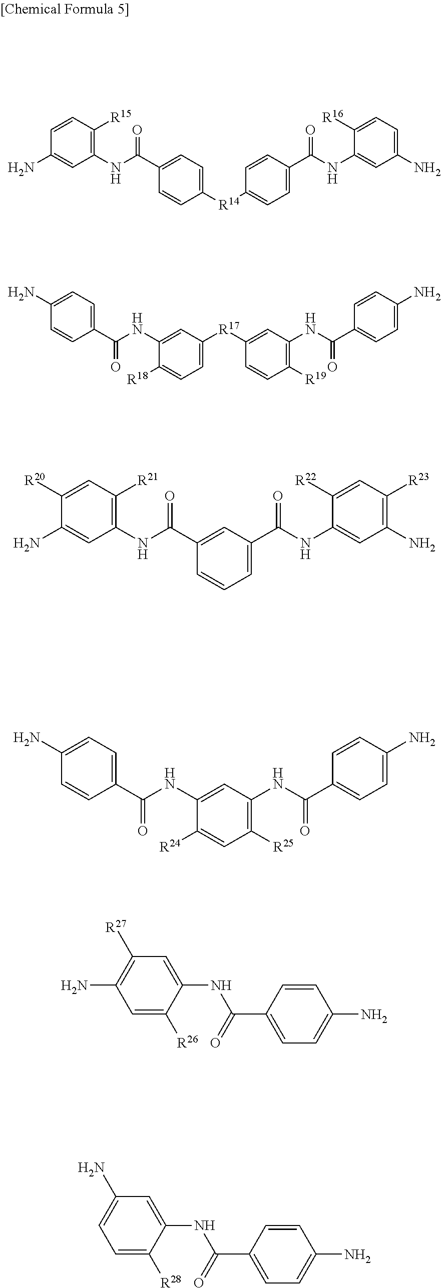

R¹⁴ and R¹⁷ each represent an oxygen atom, C(CF₃)₂, or C(CH₃)₂. R¹⁵, R¹⁶, and R¹⁸ to R²⁸ each independently represent a hydrogen atom or a hydroxyl group.

Each of these diamines may be used as a diamine, or as a corresponding diisocyanate compound or trimethylsilylated diamine.

Each of these resins may be end-capped with a monoamine having an acidic group, an anhydride, a monocarboxylic acid monoacid chloride, or a monoactive ester, to obtain a resin having an acidic group at an end of the backbone.

Preferred examples of the monoamine having an acidic group include 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 3-amino-4,6-dihydroxypyrimidine, 2-aminophenol, 3-aminophenol, 4-aminophenol, 2-aminothiophenol, 3-aminothiophenol, and 4-aminothiophenol. Two or more of these may be used.

Preferred examples of the anhydride, acid chloride, and monocarboxylic acid include anhydrides such as phthalic anhydride, maleic anhydride, nadic anhydride, cyclohexanedicarboxylic anhydride, and 3-hydroxyphthalic anhydride; monocarboxylic acids such as 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynapthalene, 1-mercapto-6-carboxynaphthalene, and 1-mercapto-5-carboxynaphthalene, and monoacid chlorides produced by conversion of the carboxyl group of these monocarboxylic acids to an acid chloride; monoacid chlorides produced by conversion of only one carboxyl group of a dicarboxylic acid such as terephthalic acid, phthalic acid, maleic acid, cyclohexanedicarboxylic acid, 1,5-dicarboxynaphthalene, 1,6-dicarboxynaphthalene, 1,7-dicarboxynaphthalene, or 2,6-dicarboxynaphthalene to an acid chloride; and monoactive esters obtained by reaction of a monoacid chloride with N-hydroxybenzotriazole or N-hydroxy-5-norbornene-2,3-dicarboximide. Two or more of these may be used.

The content of the above end-capping agents such as the monoamine, anhydride, monocarboxylic acid, monoacid chloride, and monoactive ester is preferably 2 to 25 mol % with respect to the total of 100 mol % of the acid component and the amine component constituting the resin.

The end-capping agent introduced in the resin can be simply detected by the following methods. For example, the end-capping agent can be simply detected by dissolving the resin, in which the end-capping agent is introduced, in an acidic solution to decompose the resin into the amine component and the acid component that are constituent units of the resin, and subjecting these components to gas chromatography (GC) and/or NMR measurement. Alternatively, the detection is possible by directly subjecting the resin, in which the end-capping agent is introduced, to pyrolysis-gas chromatography (PGC), infrared spectrometry, and/or ¹³C-NMR spectrometry.

The alkali-soluble resin (A) used in the present invention may be synthesized by a known method.

In cases of a polyamic acid or a polyamic acid ester, examples of the production method for its synthesis include a method in which a tetracarboxylic dianhydride is reacted with a diamine compound at low temperature, a method in which a diester is obtained from a tetracarboxylic dianhydride and an alcohol, and the diester is then reacted with an amine in the presence of a condensing agent, and a method in which a diester is obtained from a tetracarboxylic dianhydride and an alcohol, and the remaining dicarboxylic acid is then converted to an acid chloride, followed by allowing reaction with an amine.

In cases of a polybenzoxazole precursor, examples of the production method include a method in which a bisaminophenol compound is subjected to condensation reaction with a dicarboxylic acid. Specific examples of the production method include a method in which a dehydration-condensation agent such as dicyclohexylcarbodiimide (DCC) is reacted with an acid, followed by addition of a bisaminophenol compound, and a method in which a solution of a dicarboxylic acid dichloride is added dropwise to a solution of a bisaminophenol compound having a tertiary amine such as pyridine.

In cases of a polyimide, examples of the production method include a method in which a polyamic acid or a polyamic acid ester obtained by the above method is heated, or chemically treated with an acid or a base, to cause dehydration ring closure.

The photosensitive resin composition of the present invention contains a photo acid generator (B). By the inclusion of the photo acid generator (B), an acid can be generated in the irradiated area to increase solubility of the irradiated area in the aqueous alkaline solution, giving a positive relief pattern due to dissolution of the irradiated area. Further, in cases where the photo acid generator (B) and an epoxy compound or the later-mentioned thermal cross-linking agent are contained, an acid generated in the irradiated area promotes cross-linking reaction of the epoxy compound or the thermal cross-linking agent, giving a negative relief pattern due to insolubility of the irradiated area.

Examples of the photo acid generator (B) include quinone diazide compounds, sulfonium salts, phosphonium salts, diazonium salts, and iodonium salts.

Examples of the quinone diazide compounds include compounds in which sulfonate of quinone diazide is bound to a polyhydroxy compound through an ester, compounds in which sulfonate of quinone diazide is bound to a polyamino compound through a sulfonamide bond, and compounds in which sulfonate of quinone diazide is bound to a polyhydroxy polyamino compound through an ester bond and/or sulfonamide bond. In these polyhydroxy compounds and polyamino compounds, not less than 50 mol % of all functional groups are preferably substituted with quinone diazide. The composition preferably contains two or more kinds of photo acid generators (B). In such a case, a highly sensitive photosensitive resin composition can be obtained.

As the quinone diazide compound in the present invention, either a 5-naphthoquinone diazide sulfonyl group or a 4-naphthoquinone diazide sulfonyl group may be preferably used. Since 4-naphthoquinone diazide sulfonyl ester compounds have absorption in the i-ray region of mercury lamps, they are suitable for i-ray exposure. Since 5-naphthoquinone diazide sulfonyl ester compounds have absorption extending to the g-ray region of mercury lamps, they are suitable for g-ray exposure. In the present invention, it is preferred to select a 4-naphthoquinone diazide sulfonyl ester compound or a 5-naphthoquinone diazide sulfonyl ester compound according to the wavelength at which the exposure is carried out. The composition may contain a naphthoquinone diazide sulfonyl ester compound having both a 4-naphthoquinone diazide sulfonyl group and a 5-naphthoquinone diazide sulfonyl group in the same molecule, or may contain both a 4-naphthoquinone diazide sulfonyl ester compound and a 5-naphthoquinone diazide sulfonyl ester compound.

Since the quinone diazide compounds can be synthesized by esterification reaction between a compound having a phenolic hydroxyl group, and a quinone diazide sulfonate compound, the synthesis is possible by a known method. Use of these naphthoquinone diazide compounds improves the resolution, sensitivity, and residual film ratio.

Sulfonium salts, phosphonium salts, and diazonium salts are preferred as the photo acid generator (B) since they moderately stabilize the acid component generated during the exposure. Sulfonium salts are especially preferred. When necessary, the photo acid generator (B) may also contain a sensitizer or the like.

In the present invention, the content of the photo acid generator (B) is preferably not less than 0.1 parts by mass, more preferably not less than 1 part by mass, with respect to 100 parts by mass of the alkali-soluble resin (A). The content is preferably not more than 50 parts by mass, more preferably not more than 30 parts by mass. In cases where the content of the photo acid generator (B) is not less than 0.1 parts by mass, sensitivity during the exposure can be increased. In cases where the content is not more than 50 parts by mass, a decrease in the heat resistance can be suppressed. In cases of a quinone diazide compound, its content is preferably 3 to 40 parts by mass. In cases of a sulfonium salt, phosphonium salt, and/or diazonium salt, their total amount is preferably 0.5 to 20 parts by mass.

The photosensitive resin composition of the present invention contains a thermal cross-linking agent (C). The thermal cross-linking agent means a compound having, in the molecule, at least two thermally reactive functional groups such as methylol, alkoxymethyl, epoxy, and/or oxetanyl. The thermal cross-linking agent (C) is capable of cross-linking the alkali-soluble resin (A) and/or other additive components, to increase the chemical resistance and the heat resistance of the cured film.

Preferred examples of the compound having at least two alkoxymethyl and/or methylol groups include DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PTBP, DMOM-MBPC, TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA, and HMOM-TPHAP (trade names; manufactured by Honshu Chemical Industry Co., Ltd.); and “NIKALAC” (registered trademark) MX-290, “NIKALAC” (registered trademark) MX-280, “NIKALAC” (registered trademark) MX-270, “NIKALAC” (registered trademark) MX-279, “NIKALAC” (registered trademark) MW-100LM, and “NIKALAC” (registered trademark) MX-750LM (trade names; manufactured by Sanwa Chemical Co., Ltd.). These are available from the corresponding manufacturers.

Examples of the compound having epoxy and/or oxetanyl include those having two epoxy groups in the molecule, such as “Epikote” (registered trademark) 807, “Epikote” (registered trademark) 828, “Epikote” (registered trademark) 1002, “Epikote” (registered trademark) 1750, “Epikote” (registered trademark) 1007, YX8100-BH30, E1256, E4250, and E4275 (trade names; manufactured by Japan Epoxy Resin Co., Ltd.); “EPICLON” (registered trademark) EXA-4880, “EPICLON” (registered trademark) EXA-4822, “EPICLON” (registered trademark) EXA-9583, and HP4032 (trade names; manufactured by Dainippon Ink and Chemicals Inc.); “Epolight” (registered trademark) 40E, “Epolight” (registered trademark) 100E, “Epolight” (registered trademark) 200E, “Epolight” (registered trademark) 400E, “Epolight” (registered trademark) 70P, “Epolight” (registered trademark) 200P, “Epolight” (registered trademark) 400P, “Epolight” (registered trademark) 1500NP, “Epolight” (registered trademark) 80MF, “Epolight” (registered trademark) 4000, and “Epolight” (registered trademark) 3002 (trade names; manufactured by Kyoeisha Chemical Co., Ltd.); “Denacol” (registered trademark) EX-212L, “Denacol” (registered trademark) EX-214L, “Denacol” (registered trademark) EX-216L, “Denacol” (registered trademark) EX-252, and “Denacol” (registered trademark) EX-850L (trade names; manufactured by Nagase ChemteX Corporation); GAN and GOT (trade names; manufactured by Nippon Kayaku Co., Ltd.); “Celloxide” (registered trademark) 2021P (trade name; manufactured by Daicel Corporation); and “Rikaresin” (registered trademark) DME-100 and “Rikaresin” (registered trademark) BEO-60E (trade names; manufactured by New Japan Chemical Co., Ltd.). These are available from the corresponding manufacturers.

Examples of the compound having three or more epoxy groups include VG3101L (trade name; manufactured by Printec Corporation); “TEPIC” (registered trademark) S, “TEPIC” (registered trademark) G, and “TEPIC” (registered trademark) P (trade names; manufactured by Nissan Chemical Industries, Ltd.); “EPICLON” (registered trademark) N660, “EPICLON” (registered trademark) N695, and HP7200 (trade names; manufactured by Dainippon Ink and Chemicals Inc.); “Denacol” (registered trademark) EX-321L (trade name; manufactured by Nagase ChemteX Corporation); NC6000, EPPN502H, and NC3000 (trade names; manufactured by Nippon Kayaku Co., Ltd.); “Epotohto” (registered trademark) YH-434L (trade name; manufactured by Tohto Kasei Co., Ltd.); and EHPE-3150 (trade name, manufactured by Daicel Corporation). Examples of the compound having two oxetanyl groups include OXT-121, OXT-221, OX-SQ-H, OXT-191, PNOX-1009, and RSOX (trade names; manufactured by Toagosei Co., Ltd.); and “Eternacoll” (registered trademark) OXBP and “Eternacoll” (registered trademark) OXTP (trade names; manufactured by Ube Industries, Ltd.). These are available from the corresponding manufacturers.

Preferably, the thermal cross-linking agent (C) has a phenolic hydroxyl group, and also has a methylol group and/or an alkoxymethyl group at both ortho positions of the phenolic hydroxyl group, in one molecule. In the presence of the methylol group and/or the alkoxymethyl group adjacent to the phenolic hydroxyl group, an effect similar to that of the later-mentioned phenolic antioxidant (D) can be produced, so that the bending resistance after the reliability test can be further increased. Examples of the alkoxymethyl group include, but are not limited to, methoxymethyl, ethoxymethyl, propoxymethyl, and butoxymethyl.

Examples of the thermal cross-linking agent having a phenolic hydroxyl group, and also having a methylol group and/or an alkoxymethyl group at both ortho positions of the phenolic hydroxyl group in one molecule include, but are not limited to, the following.

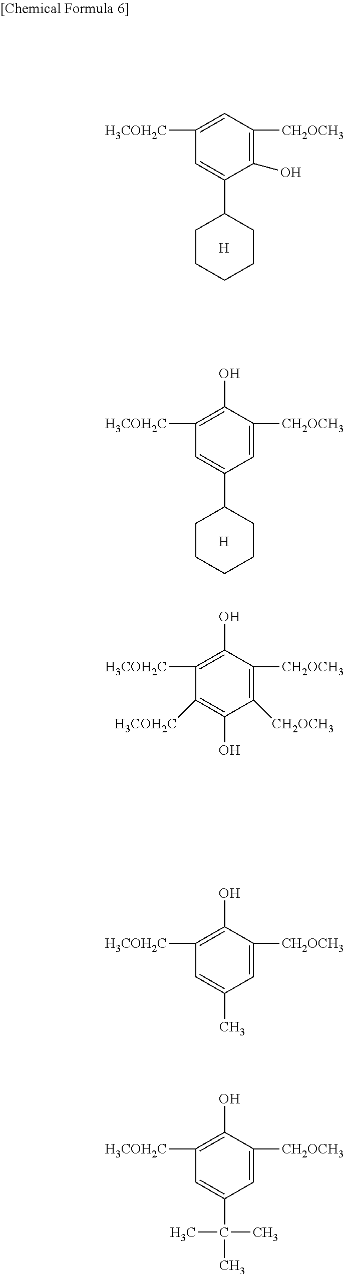

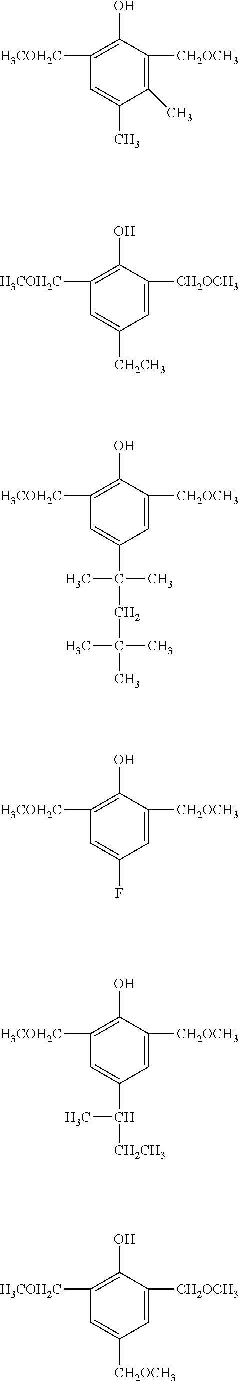

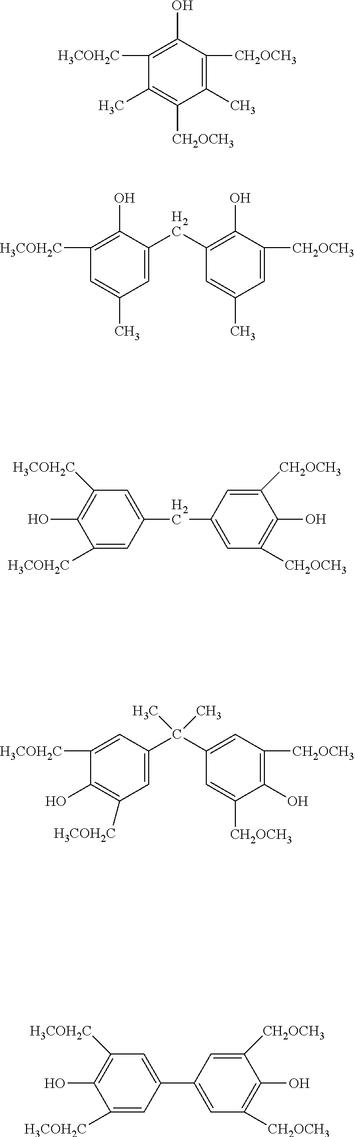

The thermal cross-linking agent (C) is preferably a cross-linking agent having three or more phenolic hydroxyl groups in one molecule. In cases where the cross-linking agent has three or more phenolic hydroxyl groups in one molecule, the antioxidant effect can be further increased, and the bending resistance after a reliability test can be further increased. Preferred examples of such a cross-linking agent include, but are not limited to, the following.

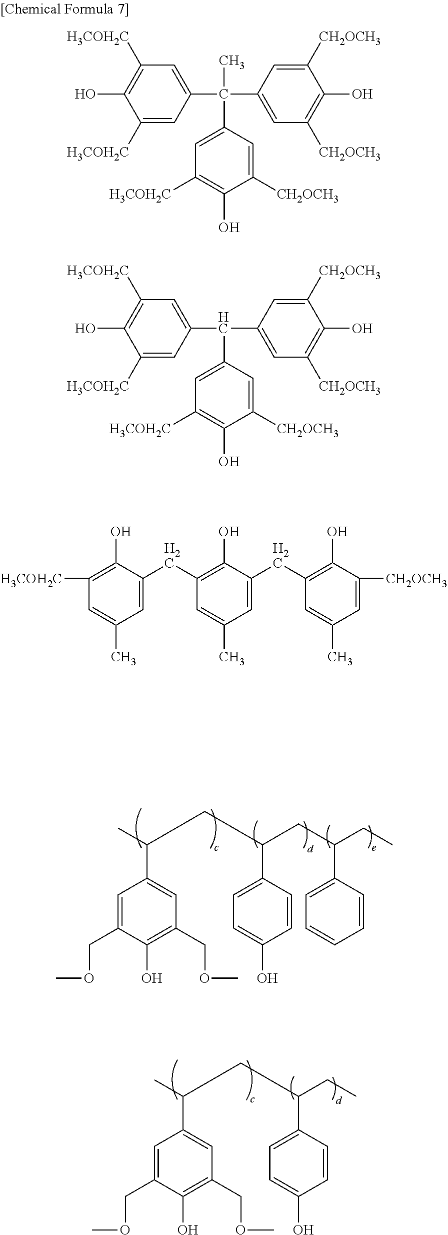

(wherein c, d, and e each represent an integer of 1 or more, and preferably satisfy 3≤c≤20, 1≤d≤30, and 1≤c≤30.)

The content of the thermal cross-linking agent (C) is preferably not less than 5 part by mass, more preferably not less than 10 part by mass, still more preferably not less than 15 parts by mass, with respect to 100 parts by mass of the alkali-soluble resin (A). The content is preferably not more than 50 parts by mass, more preferably not more than 40 parts by mass, still more preferably not more than 30 parts by mass. In cases where the content of the thermal cross-linking agent (C) is not less than 5 parts by mass, the cured film can have an improved chemical resistance. In cases where the content is not more than 50 parts by mass, a decrease in the elongation of the cured film can be prevented.

The photosensitive resin composition of the present invention contains a phenolic antioxidant (D). The phenolic antioxidant (D) means a compound having, in the molecule, a phenolic hydroxyl group, and also a bulky group at at least one of the ortho positions of the phenolic hydroxyl group. Here, the bulky group means a non-linear alkyl group, that is, a branched alkyl group, or an aromatic ring group. Specific examples of the bulky group include tertiary alkyl groups such as tert-butyl, tert-pentyl, and tert-hexyl; secondary alkyl groups such as iso-propyl, sec-butyl, and sec-pentyl; branched primary alkyl groups such as iso-butyl and iso-pentyl; cycloalkyl groups such as cyclohexyl and cyclopentyl; and aromatic ring groups such as phenyl, benzyl, and naphthyl. Among these, from the viewpoint of balancing between the heat resistance reliability and the curability, tertiary alkyl groups are more preferred. Tert-butyl is especially preferred. The phenolic antioxidant has a function which suppresses oxidative deterioration of a polymer film upon application of heat or light. Application of excessive heat or light to the cured film may cause generation of radicals in the polymer film. The generation of radicals in the polymer film may lead to further generation of unfavorable radicals and peroxides. Since such radicals and peroxides are chemically unstable, they easily react with other compounds to further generate radicals, causing a chain reaction of oxidative deterioration. This may induce deterioration of film physical properties of the cured film. The phenolic antioxidant (D) is capable of capturing radicals generated in the cured film, to suppress the deterioration of film physical properties.

Examples of the phenolic antioxidant (D) include hindered phenol antioxidants, semi-hindered phenol antioxidants, and less-hindered phenol antioxidants. The “hindered phenol antioxidants” means antioxidants in which both ortho positions of the phenolic hydroxyl group have bulky groups. The “semi-hindered phenol antioxidants” means antioxidants in which one of the ortho positions of the phenolic hydroxyl group has a bulky group, and the other has a methyl group. The “less-hindered phenol antioxidants” means antioxidants in which one of the ortho positions of the phenolic hydroxyl group has a bulky group, and the other has a hydrogen atom.

From the viewpoint of the stability of complemented radicals, the phenolic antioxidant (D) is preferably a hindered phenol antioxidant or a semi-hindered phenol antioxidant, especially preferably a hindered phenol antioxidant.

In the phenolic antioxidant (D), the phenolic hydroxyl group preferably indicates an acid dissociation constant pKa of 10.1 to 13.0 at 25° C. The acid dissociation constant (pKa) is a logarithmic value of the inverse number of the acid dissociation constant pKa in a dilute aqueous solution at 25° C. In cases of multistep dissociation, the dissociation constant in the first step (that is, pKa₁) is employed. A phenolic antioxidant indicating an acid dissociation constant pKa of 10.1 to 13.0 at 25° C. has a lower acidity of the phenolic hydroxyl group compared to that of unsubstituted phenol (pKa=10.0). The photosensitive resin composition of the present invention contains, as an essential component, either a compound (E₁) having an electron-withdrawing group and a phenolic hydroxyl group in the molecule, or a compound (E₂) having a phenolic hydroxyl group indicating an acid dissociation constant pKa of 6.0 to 9.5 at 25° C. Either of these compounds has a higher acidity of the phenolic hydroxyl group compared to that of unsubstituted phenol (pKa=10.0). As will be described later in detail, since the acidity of the phenolic hydroxyl group of the component (E₁) or (E₂) is sufficiently higher than the acidity of the phenolic antioxidant (D), denaturation of the phenolic antioxidant (D) during heat curing can be suppressed to allow improvement of the antioxidant effect for the cured film, especially the bending resistance after a reliability test.

Specific examples of the hindered phenol antioxidant include 2,6-di-tert-butylphenol, 2,6-di-tert-butyl-4-methylphenol, 2,2′-methylenebis(6-tert-butyl-4-methylphenol), 1,3,5-tris(3,5-di-tert-butyl-4-hydroxybenzyl)-1,3,5-triazine-2,4,6 (1H,3H,5H)-trione (such as “ADK STAB” (registered trademark) AO-20, manufactured by ADEKA Corporation), pentaerythritol tetrakis[3-(3,5-di-tert-butyl-4-hydroxyphenyl)propionate] (such as “ADK STAB” (registered trademark) AO-50, manufactured by ADEKA Corporation), and octadecyl-3-(3,5-di-tert-butyl-4-hydroxyphenyl)propionate (such as “ADK STAB” (registered trademark) AO-60, manufactured by ADEKA Corporation).

Specific examples of the semi-hindered phenol antioxidant include bis[3-(3-tert-butyl-4-hydroxy-5-methylphenyl)propionate][ethylenebis(oxy ethylene)] (such as “Irganox” (registered trademark) 245, manufactured by BASF Japan), 3,9-bis[1,1-dimethyl-2-[(3-tert-butyl-4-hydroxy-5-methylphenyl)propionyloxy] ethyl]-2,4,8,10-tetraoxaspiro[5.5]undecane (such as “ADK STAB” (registered trademark) AO-80, manufactured by ADEKA Corporation), and triethylene glycol bis[3-(3-tert-butyl-4-hydroxy-5-methylphenyl)propionate] (such as “ADK STAB” (registered trademark) AO-70, manufactured by ADEKA Corporation).

Specific examples of the less-hindered phenol antioxidant include 1,1,3-tris(2-methyl-4-hydroxy-5-tert-butylphenyl)butane (such as “ADK STAB” (registered trademark) AO-30, manufactured by ADEKA Corporation), 4,4′-butylidenebis(6-tert-butyl-m-cresol) (such as “ADK STAB” (registered trademark) AO-40, manufactured by ADEKA Corporation), 1,1,3-tris(2-methyl-4-hydroxy-5-tert-butylphenyl) butane (such as Topanol Calif., manufactured by ICI), 4,4′-thiobis(6-tert-butyl-m-cresol) (such as “Sumilizer” (registered trademark) WX-R, manufactured by Sumitomo Chemical Co., Ltd.), 4,4′-butylidenebis(6-tert-butyl-m-cresol) (such as “Sumilizer” (registered trademark) BBM, manufactured by Sumitomo Chemical Co., Ltd.), and 2-tert-butyl-4-methyl-6-(2-hydroxy-3-tert-butyl-5-methylbenzyl)phenyl acrylate (such as “Sumilizer” (registered trademark) GM, manufactured by Sumitomo Chemical Co., Ltd.).

The content of the phenolic antioxidant (D) is preferably not less than 0.1 parts by mass, more preferably not less than 0.5 parts by mass, still more preferably not less than 1 parts by mass, with respect to 100 parts by mass of the alkali-soluble resin (A). The content is preferably not more than 20 parts by mass, more preferably not more than 10 parts by mass, still more preferably not more than 5 parts by mass. In cases where the content of the phenolic antioxidant (D) is not less than 0.1 parts by mass, the bending resistance after a reliability test can be increased. In cases where the content is not more than 20 parts by mass, a decrease in the heat resistance can be suppressed.

The photosensitive resin composition of the present invention contains a compound (E) having a phenolic hydroxyl group other than (D). The compound having a phenolic hydroxyl group other than (D) means a compound in which a phenolic hydroxyl group is contained in the molecule; neither of the ortho positions of the phenolic hydroxyl group has a bulky group; and no thermally reactive functional group is contained. Here, the bulky group means a non-linear alkyl group, that is, a branched alkyl group, or an aromatic ring group. The thermally reactive group means a functional group capable of intermolecular cross-linking by heat treatment, such as methylol, alkoxymethyl, epoxy, and oxetanyl.

The compound (E) having a phenolic hydroxyl group other than (D) used in the present invention contains a compound (E₁) having an electron-withdrawing group and a phenolic hydroxyl group in the molecule, or a compound (E₂) having a phenolic hydroxyl group indicating an acid dissociation constant pKa of 6.0 to 9.5 at 25° C.

Here, the electron-withdrawing group of the compound (E₁) having an electron-withdrawing group and a phenolic hydroxyl group in the molecule means a substituent having an effect which decreases the charge density of the carbon atom at the α-position substituted by the substituent. It is, for example, a substituent whose Hammett substituent constant σₚ is a positive value. In the compound (E₁) having an electron-withdrawing group and a phenolic hydroxyl group in the molecule, the acidity of the phenolic hydroxyl group is high since the electron-withdrawing group is contained in the molecule. In general, the thermal cross-linking agent (C) reacts with an active hydrogen group of a compound present in the photosensitive resin film during the heat treatment step, to form a cross-linked structure. A phenolic hydroxyl group, which is an active hydrogen group, has a higher reactivity with the thermal cross-linking agent (C) as the acidity of the phenolic hydroxyl group increases. Thus, the compound (E₁) having an electron-withdrawing group and a phenolic hydroxyl group in the molecule used in the present invention has an increased reactivity with the thermal cross-linking agent (C) since the compound has the electron-withdrawing group in the molecule. Therefore, the thermal cross-linking agent (C) preferentially reacts therewith rather than with the phenolic antioxidant (D). As a result, denaturation of the phenolic antioxidant (D) during heat curing can be suppressed to allow improvement of the antioxidant effect for the cured film, especially the bending resistance after a reliability test.

Specific examples of the electron-withdrawing group include a sulfone group, sulfonyl group, sulfonic acid group, sulfonic acid ester group, sulfonic acid amide group, sulfonic acid imide group, carboxyl group, carbonyl group, carboxylic acid ester group, cyano group, halogen group, trifluoromethyl group, and nitro group. The electron-withdrawing group is not limited thereto, and may be a known arbitrary electron-withdrawing group.

In the compound (E₂) having a phenolic hydroxyl group indicating an acid dissociation constant pKa of 6.0 to 9.5 at 25° C., the acid dissociation constant (pKa) is a logarithmic value of the inverse number of the acid dissociation constant in a dilute aqueous solution at 25° C. In cases of multistep dissociation, the dissociation constant in the first step (that is, pKa₁) is employed. The compound (E₂) having a phenolic hydroxyl group indicating an acid dissociation constant pKa of 6.0 to 9.5 at 25° C. has a higher acidity of the phenolic hydroxyl group compared to that of unsubstituted phenol (pKa=10.0). In general, the thermal cross-linking agent (C) reacts with an active hydrogen group of a compound present in the photosensitive resin film during the heat treatment step, to form a cross-linked structure. A phenolic hydroxyl group, which is an active hydrogen group, has a higher reactivity with the thermal cross-linking agent (C) as the acidity of the phenolic hydroxyl group increases. Thus, the compound (E₂) having a phenolic hydroxyl group indicating an acid dissociation constant pKa of 6.0 to 9.5 at 25° C. used in the photosensitive resin composition of the present invention has an increased reactivity with the thermal cross-linking agent (C) since the phenolic hydroxyl group has a high acidity. Therefore, the thermal cross-linking agent (C) preferentially reacts therewith rather than with the phenolic antioxidant (D). As a result, denaturation of the phenolic antioxidant (D) during heat curing can be suppressed to allow improvement of the antioxidant effect for the cured film, especially the bending resistance after a reliability test. In cases where the acid dissociation constant pKa of the compound (E₂) at 25° C. is not more than 9.5, reactivity with the thermal cross-linking agent (C) can be increased, and, as a result, denaturation of the phenolic antioxidant (D) during heat curing can be suppressed to allow improvement of the antioxidant effect for the cured film, especially the bending resistance after a reliability test. The acid dissociation constant pKa of the compound (E₂) at 25° C. is preferably not more than 9.2, more preferably not more than 9.0, still more preferably not more than 8.5. In cases where the acid dissociation constant pKa at 25° C. is not less than 6.0, the storage stability of the photosensitive resin composition at room temperature can be increased. The acid dissociation constant pKa is preferably not less than 6.3, more preferably not less than 6.6, still more preferably not less than 7.0.

The compound (E₁) having an electron-withdrawing group and a phenolic hydroxyl group in the molecule, or the compound (E₂) having a phenolic hydroxyl group indicating an acid dissociation constant pKa of 6.0 to 9.5 at 25° C., preferably has two or more phenolic hydroxyl groups in the molecule. In cases where the molecule has two or more phenolic hydroxyl groups therein, two or more reaction sites for the thermal cross-linking agent (C) are present, so that the cross-linking density of the cured film can be increased to improve the chemical resistance.

In the compound (E₁) having an electron-withdrawing group and a phenolic hydroxyl group in the molecule, or the compound (E₂) having a phenolic hydroxyl group indicating an acid dissociation constant pKa of 6.0 to 9.5 at 25° C., both ortho positions of the phenolic hydroxyl group preferably have hydrogen atoms. In cases where both ortho positions of the phenolic hydroxyl group have hydrogen atoms, that is, in cases where neither of the ortho positions has a bulky group, reactivity with the thermal cross-linking agent (C) can be further increased. Therefore, the thermal cross-linking agent (C) preferentially reacts with the compound (E₁) or (E₂) rather than with the phenolic antioxidant (D). As a result, denaturation of the phenolic antioxidant (D) during heat curing can be further suppressed to allow further improvement of the antioxidant effect for the cured film, especially the bending resistance after a reliability test.

Preferred examples of the compound (E₁) having an electron-withdrawing group and a phenolic hydroxyl group in the molecule, or the compound (E₂) having a phenolic hydroxyl group indicating an acid dissociation constant pKa of 6.0 to 9.5 at 25° C., include the compounds represented by General Formula (3).

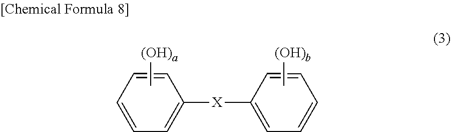

(wherein in General Formula (3), X represents any group selected from the group consisting of carbonyl, sulfonyl, and hexafluoroisopropyl; a and b each represent an integer of 0 to 3; and a+b is an integer of 2 to 4.)

Specific examples of the compounds represented by General Formula (3) include 2,2′-dihydroxybenzophenone, 4,4′-dihydroxybenzophenone, 2,4-dihydroxybenzophenone, 3,4-dihydroxybenzophenone, 2,3,4-trihydroxybenzophenone, 2,4,4′-trihydroxybenzophenone, 2,3,4,4′-tetrahydroxybenzophenone, 2,2′,4,4′-tetrahydroxybenzophenone, bisphenol S, and bisphenol AF.

Specific examples other than the compounds represented by General Formula (3) include 2-fluorophenol, 3-fluorophenol, 4-fluorophenol, 2,4-difluorophenol, 2,6-difluorophenol, 3,4-difluorophenol, 3,5-difluorophenol, 2,4,6-trifluorophenol, 3,4,5-trifluorophenol, 2,3,5,6-tetrafluorophenol, pentafluorophenol, 2,3,5,6-tetrafluoro-4-trifluoromethylphenol, 2,3,5,6-tetrafluoro-4-pentafluorophenylphenol, perfluoro-1-naphthol, perfluoro-2-naphthol, 2-chlorophenol, 3-chlorophenol, 4-chlorophenol, 2,4-dichlorophenol, 2,6-dichlorophenol, 3,4-dichlorophenol, 3,5-dichlorophenol, 2,4,6-trichlorophenol, 3,4,5-trichlorophenol, 2,3,5,6-tetrachlorophenol, pentachlorophenol, 2,3,5,6-tetrachloro-4-trichloromethylphenol, 2,3,5,6-tetrachloro-4-pentachlorophenylphenol, perchloro-1-naphthol, perchloro-2-naphthol, 2-bromophenol, 3-bromophenol, 4-bromophenol, 2,4-dibromophenol, 2,6-dibromophenol, 3,4-dibromophenol, 3,5-dibromophenol, 2,4,6-tribromophenol, 3,4,5-tribromophenol, 2,3,5,6-tetrabromophenol, pentabromophenol, 2,3,5,6-tetrabromo-4-tribromomethylphenol, 2,3,5,6-tetrabromo-4-pentabromophenylphenol, perbromo-1-naphthol, perbromo-2-naphthol, 2-iodophenol, 3-iodophenol, 4-iodophenol, 2,4-diiodophenol, 2,6-diiodophenol, 3,4-diiodophenol, 3,5-diiodophenol, 2,4,6-triiodophenol, 3,4,5-triiodophenol, 2,3,5,6-tetraiodophenol, pentaiodophenol, 2,3,5,6-tetraiodo-4-triiodomethylphenol, 2,3,5,6-tetraiodo-4-pentaiodophenylphenol, periodo-1-naphthol, periodo-2-naphthol, 2-(trifluoromethyl)phenol, 3-(trifluoromethyl)phenol, 4-(trifluoromethyl)phenol, 2,6-bis(trifluoromethyl)phenol, 3,5-bis(trifluoromethyl)phenol, 2,4,6-tris(trifluoromethyl)phenol, 2-cyanophenol, 3-cyanophenol, 4-cyanophenol, 2-nitrophenol, 3-nitrophenol, 4-nitrophenol, 2-hydroxyacetophenone, 3-hydroxyacetophenone, 4-hydroxyacetophenone, salicylic acid, and methyl salicylate.

The content of the compound (E₁) having an electron-withdrawing group and a phenolic hydroxyl group in the molecule, or the compound (E₂) having a phenolic hydroxyl group indicating an acid dissociation constant pKa of 6.0 to 9.5 at 25° C., is preferably not less than 1 part by mass, more preferably not less than 5 parts by mass, still more preferably not less than 10 parts by mass, with respect to 100 parts by mass of the alkali-soluble resin (A). The content is preferably not more than 40 parts by mass, more preferably not more than 30 parts by mass, still more preferably not more than 20 parts by mass. In cases where the content of the compound (E₁) having an electron-withdrawing group and a phenolic hydroxyl group in the molecule, or the compound (E₂) having a phenolic hydroxyl group indicating an acid dissociation constant pKa of 6.0 to 9.5 at 25° C., is not less than 1 part by mass, the bending resistance after a reliability test can be increased. In cases where the content is not more than 40 parts by mass, a decrease in the heat resistance can be suppressed.

In the photosensitive resin composition of the present invention, the mass ratio between the content of the phenolic antioxidant (D) and the content of the compound (E₁) having an electron-withdrawing group and a phenolic hydroxyl group in the molecule (E₁/D) is preferably 2 to 40. In cases where (E₁/D) is not less than 2, reaction between the thermal cross-linking agent (C) and the phenolic antioxidant (D) during the heat treatment step can be effectively suppressed. As a result, denaturation of the phenolic antioxidant (D) during heat curing can be suppressed to allow improvement of the antioxidant effect for the cured film, especially the bending resistance after a reliability test. In cases where (E₁/D) is not more than 40, it is possible to suppress a decrease in the heat resistance due to an excessive content of the compound (E₁) having an electron-withdrawing group and a phenolic hydroxyl group in the molecule. (E₁/D) is more preferably not less than 3, still more preferably not less than 5, and is more preferably not more than 30, still more preferably not more than 20.

In the photosensitive resin composition of the present invention, the mass ratio between the content of the phenolic antioxidant (D) and the content of the compound (E₂) having a phenolic hydroxyl group indicating an acid dissociation constant pKa of 6.0 to 9.5 at 25° C. (E₂/D) is preferably 2 to 40. In cases where (E₂/D) is not less than 2, reaction between the thermal cross-linking agent (C) and the phenolic antioxidant (D) during the heat treatment step can be effectively suppressed. As a result, denaturation of the phenolic antioxidant (D) during heat curing can be suppressed to allow improvement of the antioxidant effect for the cured film, especially the bending resistance after a reliability test. In cases where (E₂/D) is not more than 40, it is possible to suppress a decrease in the heat resistance due to an excessive content of the compound (E₁) having an electron-withdrawing group and a phenolic hydroxyl group in the molecule. (E₂/D) is more preferably not less than 3, still more preferably not less than 5, and is more preferably not more than 30, still more preferably not more than 20. Regarding the compound (E) having a phenolic hydroxyl group other than (D) used in the photosensitive resin composition of present invention, when necessary, a compound other than (E₁) or (E₂), that is, a compound (E3) having no electron-withdrawing group, but having a phenolic hydroxyl group in the molecule, may be used in combination with the (E₁) compound or the (E₂) compound. Examples of the compound (E3) having no electron-withdrawing group, but having a phenolic hydroxyl group in the molecule, include Bis-Z, BisOC-Z, BisOPP-Z, BisP-CP, Bis26X-Z, BisOTBP-Z, BisOCHP-Z, BisOCR-CP, BisP-MZ, BisP-EZ, Bis26X-CP, BisP-PZ, BisP-IPZ, BisCRIPZ, BisOCP-IPZ, BisOIPP-CP, Bis26X-IPZ, BisOTBP-CP, TekP-4HBPA (tetrakis P-DO-BPA), TrisP-HAP, TrisP-PA, TrisP-PHBA, TrisP-SA, TrisOCR-PA, BisOFP-Z, BisRS-2P, BisPG-26X, BisRS-3P, BisOC-OCHP, BisPC-OCHP, Bis25X-OCHP, Bis26X-OCHP, BisOCHP-OC, Bis236T-OCHP, methylenetris-FR-CR, BisRS-26X, and BisRS-OCHP (trade names; manufactured by Honshu Chemical Industry Co., Ltd.); BIR-OC, BIP-PCBIR-PC, BIR-PTBP, BIR-PCHP, BIP-BIOC-F, 4PC, BIR-BIPC-F, and TEP-BIP-A (trade names; manufactured by Asahi Yukizai Corporation); 1,4-dihydroxynaphthalene, 1,5-dihydroxynaphthalene, 1,6-dihydroxynaphthalene, 1,7-dihydroxynaphthalene, 2,3-dihydroxynaphthalene, 2,6-dihydroxynaphthalene, 2,7-dihydroxynaphthalene, 2,4-dihydroxyquinoline, 2,6-dihydroxyquinoline, 2,3-dihydroxyquinoxaline, anthracene-1,2,10-triol, anthracene-1,8,9-triol, and 8-quinolinol. These are available from the corresponding manufacturers. By inclusion of such a compound (E3) having no electron-withdrawing group, but having a phenolic hydroxyl group in the molecule, the resulting photosensitive resin composition can have an increased solubility in an alkaline developer, and the development time can therefore be reduced.

The content of the compound (E₃) having no electron-withdrawing group, but having a phenolic hydroxyl group in the molecule is preferably not less than 1 part by mass, more preferably not less than 5 parts by mass, with respect to 100 parts by mass of the alkali-soluble resin (A). The content is preferably not more than 20 parts by mass, more preferably not more than 10 parts by mass. In cases where the content of the compound (E₃) having no electron-withdrawing group, but having a phenolic hydroxyl group in the molecule, is not less than 1 part by mass, the development time can be reduced. In cases where the content is not more than 20 parts by mass, a decrease in the heat resistance can be suppressed.

The photosensitive resin composition of the present invention may contain a coloring agent (F). The coloring agent (F) means an organic pigment, an inorganic pigment, or a dye which is generally used in the field of electronic information materials. The coloring agent (F) may preferably be an organic pigment and/or an inorganic pigment.

Examples of the organic pigment include diketopyrrolopyrrole-based pigments; azo-based pigments such as azo-, disazo-, or polyazo-based pigments; phthalocyanine-based pigments such as copper phthalocyanine, copper halide phthalocyanine, and metal-free phthalocyanine; anthraquinone-based pigments such as aminoanthraquinone, diaminoanthraquinone, anthrapyrimidine, flavanthrone, anthanthrone, indanthrone, pyranthrone, and violanthrone; quinacridone-based pigments; dioxazine-based pigments; perinone-based pigments; perylene-based pigments; thioindigo-based pigments; isoindoline-based pigments; isoindolinone-based pigments; quinophthalone-based pigments; threne-based pigments; benzofuranone-based; and metal complex-based pigments.

Examples of the inorganic pigment include titanium oxide, zinc white, zinc sulfide, white lead, calcium carbonate, precipitated barium sulfate, white carbon, alumina white, kaolin clay, talc, bentonite, black iron oxide, cadmium red, red oxide, molybdenum red, molybdate orange, chromium vermilion, chrome yellow, cadmium yellow, yellow iron oxide, titanium yellow, chromic oxide, viridian, titanium cobalt green, cobalt green, cobalt chrome green, victoria green, ultramarine blue, Prussian blue, cobalt blue, cerulean blue, cobalt silica blue, cobalt zinc silica blue, manganese violet, and cobalt violet.

Examples of the dye include azo dyes, anthraquinone dyes, condensed polycyclic aromatic carbonyl dyes, indigoid dyes, carbonium dyes, phthalocyanine dyes, and methine or polymethine dyes.

As red pigments, examples of the coloring agent include Pigment Red 9, Pigment Red 48, Pigment Red 97, Pigment Red 122, Pigment Red 123, Pigment Red 144, Pigment Red 149, Pigment Red 166, Pigment Red 168, Pigment Red 177, Pigment Red 179, Pigment Red 180, Pigment Red 192, Pigment Red 209, Pigment Red 215, Pigment Red 216, Pigment Red 217, Pigment Red 220, Pigment Red 223, Pigment Red 224, Pigment Red 226, Pigment Red 227, Pigment Red 228, Pigment Red 240, and Pigment Red 254 (each numeral represents a color index (hereinafter referred to as “CI” number)).

As orange pigments, examples of the coloring agent include Pigment Orange 13, Pigment Orange 36, Pigment Orange 38, Pigment Orange 43, Pigment Orange 51, Pigment Orange 55, Pigment Orange 59, Pigment Orange 61, Pigment Orange 64, Pigment Orange 65, and Pigment Orange 71 (each numeral represents a CI number).

As yellow pigments, examples of the coloring agent include Pigment Yellow 12, Pigment Yellow 13, Pigment Yellow 17, Pigment Yellow 20, Pigment Yellow 24, Pigment Yellow 83, Pigment Yellow 86, Pigment Yellow 93, Pigment Yellow 95, Pigment Yellow 109, Pigment Yellow 110, Pigment Yellow 117, Pigment Yellow 125, Pigment Yellow 129, Pigment Yellow 137, Pigment Yellow 138, Pigment Yellow 139, Pigment Yellow 147, Pigment Yellow 148, Pigment Yellow 150, Pigment Yellow 153, Pigment Yellow 154, Pigment Yellow 166, Pigment Yellow 168, and Pigment Yellow 185 (each numeral represents a CI number).

As violet pigments, examples of the coloring agent include Pigment Violet 19, Pigment Violet 23, Pigment Violet 29, Pigment Violet 30, Pigment Violet 32, Pigment Violet 37, Pigment Violet 40, and Pigment Violet 50 (each numeral represents a CI number).

As blue pigments, examples of the coloring agent include Pigment Blue 15, Pigment Blue 15:3, Pigment Blue 15:4, Pigment Blue 15:6, Pigment Blue 22, Pigment Blue 60, and Pigment Blue 64 (each numeral represents a CI number).

As green pigments, examples of the coloring agent include Pigment Green 7, Pigment Green 10, Pigment Green 36, and Pigment Green 58 (each numeral represents a CI number).

As black pigments, examples of the coloring agent include black organic pigments and black inorganic pigments. Examples of the black organic pigments include carbon black, benzofuranone-based black pigments (described in WO 2010/081624), perylene-based black pigments, aniline-based black pigments, and anthraquinone-based black pigments. Among these, benzofuranone-based black pigments and perylene-based black pigments are especially preferred since a negative-type photosensitive resin composition having higher sensitivity can be obtained therewith. This is because benzofuranone-based black pigments and perylene-based black pigments show low transmittance in the visible region to realize high light-shielding properties in the visible region, while they show relatively high transmittance in the ultraviolet region to allow efficient chemical reaction during the exposure. The composition may contain both a benzofuranone-based black pigment and a perylene-based black pigment. Examples of the black inorganic pigments include microparticles of graphite or a metal such as titanium, copper, iron, manganese, cobalt, chromium, nickel, zinc, calcium, or silver; oxides; composite oxides; sulfides; nitrides; and oxynitrides. Carbon black or titanium nitride is preferred because of its high light-shielding properties.

As white pigments, examples of the coloring agent include titanium dioxide, barium carbonate, zirconium oxide, calcium carbonate, barium sulfate, alumina white, and silicon dioxide.

As dyes, examples of the coloring agent include Direct Red 2, Direct Red 4, Direct Red 9, Direct Red 23, Direct Red 26, Direct Red 28, Direct Red 31, Direct Red 39, Direct Red 62, Direct Red 63, Direct Red 72, Direct Red 75, Direct Red 76, Direct Red 79, Direct Red 80, Direct Red 81, Direct Red 83, Direct Red 84, Direct Red 89, Direct Red 92, Direct Red 95, Direct Red 111, Direct Red 173, Direct Red 184, Direct Red 207, Direct Red 211, Direct Red 212, Direct Red 214, Direct Red 218, Direct Red 221, Direct Red 223, Direct Red 224, Direct Red 225, Direct Red 226, Direct Red 227, Direct Red 232, Direct Red 233, Direct Red 240, Direct Red 241, Direct Red 242, Direct Red 243, and Direct Red 247; Acid Red 35, Acid Red 42, Acid Red 51, Acid Red 52, Acid Red 57, Acid Red 62, Acid Red 80, Acid Red 82, Acid Red 111, Acid Red 114, Acid Red 118, Acid Red 119, Acid Red 127, Acid Red 128, Acid Red 131, Acid Red 143, Acid Red 145, Acid Red 151, Acid Red 154, Acid Red 157, Acid Red 158, Acid Red 211, Acid Red 249, Acid Red 254, Acid Red 257, Acid Red 261, Acid Red 263, Acid Red 266, Acid Red 289, Acid Red 299, Acid Red 301, Acid Red 305, Acid Red 319, Acid Red 336, Acid Red 337, Acid Red 361, Acid Red 396, and Acid Red 397; Reactive Red 3, Reactive Red 13, Reactive Red 17, Reactive Red 19, Reactive Red 21, Reactive Red 22, Reactive Red 23, Reactive Red 24, Reactive Red 29, Reactive Red 35, Reactive Red 37, Reactive Red 40, Reactive Red 41, Reactive Red 43, Reactive Red 45, Reactive Red 49, and Reactive Red 55; Basic Red 12, Basic Red 13, Basic Red 14, Basic Red 15, Basic Red 18, Basic Red 22, Basic Red 23, Basic Red 24, Basic Red 25, Basic Red 27, Basic Red 29, Basic Red 35, Basic Red 36, Basic Red 38, Basic Red 39, Basic Red 45, and Basic Red 46; Direct Violet 7, Direct Violet 9, Direct Violet 47, Direct Violet 48, Direct Violet 51, Direct Violet 66, Direct Violet 90, Direct Violet 93, Direct Violet 94, Direct Violet 95, Direct Violet 98, Direct Violet 100, and Direct Violet 101; Acid Violet 5, Acid Violet 9, Acid Violet 11, Acid Violet 34, Acid Violet 43, Acid Violet 47, Acid Violet 48, Acid Violet 51, Acid Violet 75, Acid Violet 90, Acid Violet 103, and Acid Violet 126; Reactive Violet 1, Reactive Violet 3, 4, Reactive Violet 5, Reactive Violet 6, Reactive Violet 7, Reactive Violet 8, Reactive Violet 9, Reactive Violet 16, Reactive Violet 17, Reactive Violet 22, Reactive Violet 23, Reactive Violet 24, Reactive Violet 26, Reactive Violet 27, Reactive Violet 33, and Reactive Violet 34; Basic Violet 1, Basic Violet 2, Basic Violet 3, Basic Violet 7, Basic Violet 10, Basic Violet 15, Basic Violet 16, Basic Violet 20, Basic Violet 21, Basic Violet 25, Basic Violet 27, Basic Violet 28, Basic Violet 35, Basic Violet 37, Basic Violet 39, Basic Violet 40, and Basic Violet 48; Direct Yellow 8, Direct Yellow 9, Direct Yellow 11, Direct Yellow 12, Direct Yellow 27, Direct Yellow 28, Direct Yellow 29, Direct Yellow 33, Direct Yellow 35, Direct Yellow 39, Direct Yellow 41, Direct Yellow 44, Direct Yellow 50, Direct Yellow 53, Direct Yellow 58, Direct Yellow 59, Direct Yellow 68, Direct Yellow 87, Direct Yellow 93, Direct Yellow 95, Direct Yellow 96, Direct Yellow 98, Direct Yellow 100, Direct Yellow 106, Direct Yellow 108, Direct Yellow 109, Direct Yellow 110, Direct Yellow 130, Direct Yellow 142, Direct Yellow 144, Direct Yellow 161, and Direct Yellow 163; Acid Yellow 17, Acid Yellow 19, Acid Yellow 23, Acid Yellow 25, Acid Yellow 39, Acid Yellow 40, Acid Yellow 42, Acid Yellow 44, Acid Yellow 49, Acid Yellow 50, Acid Yellow 61, Acid Yellow 64, Acid Yellow 76, Acid Yellow 79, Acid Yellow 110, Acid Yellow 127, Acid Yellow 135, Acid Yellow 143, Acid Yellow 151, Acid Yellow 159, Acid Yellow 169, Acid Yellow 174, Acid Yellow 190, Acid Yellow 195, Acid Yellow 196, Acid Yellow 197, Acid Yellow 199, Acid Yellow 218, Acid Yellow 219, Acid Yellow 222, and Acid Yellow 227; Reactive Yellow 2, Reactive Yellow 3, Reactive Yellow 13, Reactive Yellow 14, Reactive Yellow 15, Reactive Yellow 17, Reactive Yellow 18, Reactive Yellow 23, Reactive Yellow 24, Reactive Yellow 25, Reactive Yellow 26, Reactive Yellow 27, Reactive Yellow 29, Reactive Yellow 35, Reactive Yellow 37, Reactive Yellow 41, and Reactive Yellow 42; Basic Yellow 1, Basic Yellow 2, 4, Basic Yellow 11, Basic Yellow 13, Basic Yellow 14, Basic Yellow 15, Basic Yellow 19, Basic Yellow 21, Basic Yellow 23, Basic Yellow 24, Basic Yellow 25, Basic Yellow 28, Basic Yellow 29, Basic Yellow 32, Basic Yellow 36, Basic Yellow 39, and Basic Yellow 40; Acid Green 16; Acid Blue 9, Acid Blue 45, Acid Blue 80, Acid Blue 83, Acid Blue 90, and Acid Blue 185; and Basic Orange 21 and Basic Orange 23 (each numeral represents a CI number); Sumilan and “Lanyl” (registered trademark) series (manufactured by Sumitomo Chemical Co., Ltd.); “Orasol” (registered trademark), “Oracet” (registered trademark), “Filamid” (registered trademark), “Irgasperse” (registered trademark), Zapon, “Neozapon” (registered trademark), Neptune, and Acidol series (manufactured by BASF); “Kayaset” (registered trademark) and “Kayakalan” (registered trademark) series (manufactured by Nippon Kayaku Co., Ltd.); “Valifast” (registered trademark) Colors series (manufactured by Orient Chemical Industries Co., Ltd.); Savinyl, Sandoplast, “Polysynthren” (registered trademark), and “Lanasyn” (registered trademark) series (manufactured by Clariant Japan K. K.); “Aizen” (registered trademark) and “Spilon” (registered trademark) series (manufactured by Hodogaya Chemical Co., Ltd.); functional dyes (manufactured by Yamada Chemical Co., Ltd.); and Plast Color and Oil Color series (manufactured by Arimoto Chemical Co., Ltd.).

For the purpose of increasing the contrast of the organic EL display device, the color of the coloring agent is preferably black, which enables blocking of visible light throughout its wavelength range. In this case, a coloring agent that makes the prepared cured film exhibit a black color may be employed by using at least one selected from organic pigments, inorganic pigments, and dyes. For such a purpose, a black organic pigment or a black inorganic pigment described above may be used, or two or more kinds of organic pigments and/or dyes may be mixed to produce a pseudo-black color. In cases where the pseudo-black color is produced, it may be obtained by mixing two or more of the above organic pigments and dyes having, for example, a red, orange, yellow, violet, blue, or green color. It should be noted that the photosensitive resin composition of the present invention itself does not necessarily need to have a black color. A coloring agent whose color changes during the heat curing, to make the cured film exhibit a black color may also be used.

Among these, from the viewpoint of securing high heat resistance, a coloring agent which contains an organic pigment and/or an inorganic pigment, and which makes the cured film exhibit a black color, is preferably used. From the viewpoint of securing high insulation properties, a coloring agent which contains an organic pigment and/or a dye, and which makes the cured film exhibit a black color, is preferably used. Thus, from the viewpoint of achieving both high heat resistance and high insulation properties, a coloring agent which contains an organic pigment, and which makes the cured film exhibit a black color, is preferably used.

The content of coloring agent (F) is preferably not less than 10 parts by mass, more preferably not less than 20 parts by mass, still more preferably not less than 30 parts by mass, and is preferably not more than 300 parts by mass, more preferably not more than 200 parts by mass, still more preferably not more than 150 parts by mass, with respect to 100 parts by mass of the alkali-soluble resin (A). In cases where the content of the coloring agent is not less than 10 parts by mass, colorability required for the cured film can be obtained. In cases where the content is not more than 300 parts by mass, favorable storage stability can be achieved.

In cases where a pigment is used as the coloring agent (F) in the photosensitive resin composition of the present invention, a dispersant is preferably used in combination. By the combined use of a dispersant, the coloring agent can be homogeneously and stably dispersed in the resin composition. The dispersant is not limited, and is preferably a polymer dispersant. Examples of the polymer dispersant include polyester-based polymer dispersants, acrylic-based polymer dispersants, polyurethane-based polymer dispersants, polyallylamine-based polymer dispersants, and carbodiimide-based polymer dispersants. More specifically, the polymer dispersant means a polymer compound whose backbone is composed of a polyamino, polyether, polyester, polyurethane, polyacrylate, or the like, and which has a polar group such as amine, carboxylic acid, phosphoric acid, amine salt, carboxylic acid salt, or phosphoric acid salt in a side chain or at an end of the backbone. Adsorption of the polar group to the pigment causes steric hindrance of the backbone polymer, to stabilize dispersion of the pigment.

Dispersants can be classified into (polymer) dispersants having only an amine number, (polymer) dispersants having only an acid number, (polymer) dispersants having an amine number and an acid number, and (polymer) dispersants having neither an amine number nor an acid number. (Polymer) dispersants having an amine number and an acid number, and (polymer) dispersants having only an amine number are preferred. (Polymer) dispersants having only an amine number are more preferred.

Specific examples of the (polymer) dispersants having only an amine number include “DISPERBYK” (registered trademark) 102, “DISPERBYK” (registered trademark) 160, “DISPERBYK” (registered trademark) 161, “DISPERBYK” (registered trademark) 162, “DISPERBYK” (registered trademark) 2163, “DISPERBYK” (registered trademark) 164, “DISPERBYK” (registered trademark) 2164, “DISPERBYK” (registered trademark) 166, “DISPERBYK” (registered trademark) 167, “DISPERBYK” (registered trademark) 168, “DISPERBYK” (registered trademark) 2000, “DISPERBYK” (registered trademark) 2050, “DISPERBYK” (registered trademark) 2150, “DISPERBYK” (registered trademark) 2155, “DISPERBYK” (registered trademark) 9075, “DISPERBYK” (registered trademark) 9077, BYK-LP N6919, BYK-LP N21116, and BYK-LP N21234 (manufactured by BYK-Chemie Japan K. K.); “EFKA” (registered trademark) 4015, “EFKA” (registered trademark) 4020, “EFKA” (registered trademark) 4046, “EFKA” (registered trademark) 4047, “EFKA” (registered trademark) 4050, “EFKA” (registered trademark) 4055, “EFKA” (registered trademark) 4060, “EFKA” (registered trademark) 4080, “EFKA” (registered trademark) 4300, “EFKA” (registered trademark) 4330, “EFKA” (registered trademark) 4340, “EFKA” (registered trademark) 4400, “EFKA” (registered trademark) 4401, “EFKA” (registered trademark) 4402, “EFKA” (registered trademark) 4403, and “EFKA” (registered trademark) 4800 (manufactured by BASF Japan); “Ajisper” (registered trademark) PB711 (manufactured by Ajinomoto Fine-Techno Co., Inc.); and “SOLSPERSE” (registered trademark) 13240, “SOLSPERSE” (registered trademark) 13940, “SOLSPERSE” (registered trademark) 20000, “SOLSPERSE” (registered trademark) 71000, and “SOLSPERSE” (registered trademark) 76500 (manufactured by Lubrizol Corporation).

Among the polymer dispersants having only an amine number, from the viewpoint of enabling finer pigment dispersion, and reducing the surface roughness, that is, improving the smoothness of the film surface of the cured film obtained from the photosensitive resin composition, polymer dispersants having a basic functional group, for example, a tertiary amino group or a nitrogen-containing heterocycle such as pyridine, pyrimidine, pyrazine, or isocyanurate, as a pigment-adsorbing group are preferred. Examples of the polymer dispersants having a basic functional group which is a tertiary amino group or a nitrogen-containing heterocycle include “DISPERBYK” (registered trademark) 164, “DISPERBYK” (registered trademark) 167, BYK-LP N6919, and BYK-LP N21116; and “SOLSPERSE” (registered trademark) 20000.

Examples of the polymer dispersants having an amine number and an acid number include “DISPERBYK” (registered trademark) 142, “DISPERBYK” (registered trademark) 145, “DISPERBYK” (registered trademark) 2001, “DISPERBYK” (registered trademark) 2010, “DISPERBYK” (registered trademark) 2020, “DISPERBYK” (registered trademark) 2025, “DISPERBYK” (registered trademark) 9076, and “Anti-Terra” (registered trademark)-205 (manufactured by BYK-Chemie Japan K. K.); “Ajisper” (registered trademark) PB821, “Ajisper” (registered trademark) PB880, and “Ajisper” (registered trademark) PB881 (manufactured by Ajinomoto Fine-Techno Co., Inc.); and “SOLSPERSE” (registered trademark) 9000, “SOLSPERSE” (registered trademark) 11200, “SOLSPERSE” (registered trademark) 13650, “SOLSPERSE” (registered trademark) 24000, “SOLSPERSE” (registered trademark) 24000SC, “SOLSPERSE” (registered trademark) 24000GR, “SOLSPERSE” (registered trademark) 32000, “SOLSPERSE” (registered trademark) 32500, “SOLSPERSE” (registered trademark) 32550, “SOLSPERSE” (registered trademark) 326000, “SOLSPERSE” (registered trademark) 33000, “SOLSPERSE” (registered trademark) 34750, “SOLSPERSE” (registered trademark) 35100, “SOLSPERSE” (registered trademark) 35200, “SOLSPERSE” (registered trademark) 37500, “SOLSPERSE” (registered trademark) 39000, and “SOLSPERSE” (registered trademark) 56000 (manufactured by Lubrizol Corporation).

The ratio of the dispersant to the coloring agent is preferably not less than 1% by mass, more preferably not less than 3% by mass for increasing the dispersion stability while maintaining the heat resistance. The ratio is preferably not more than 100% by mass, more preferably not more than 50% by mass.

The photosensitive resin composition of the present invention preferably contains an organic solvent. Examples of the organic solvent include compounds such as ethers, acetates, esters, ketones, aromatic hydrocarbons, amides, and alcohols.

Specific examples of the organic solvent include ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, dipropylene glycol dimethyl ether, dipropylene glycol methyl-n-butyl ether, tripropylene glycol monomethyl ether, tripropylene glycol monoethyl ether, diethylene glycol dimethyl ether, diethylene glycol methyl ethyl ether, diethylene glycol diethyl ether, and tetrahydrofuran; acetates such as butyl acetate, ethylene glycol monomethyl ether acetate, ethylene glycol monoethyl ether acetate, propylene glycol monomethyl ether acetate, 3-methoxybutyl acetate, ethylene glycol monobutyl ether acetate, diethylene glycol monomethyl ether acetate, diethylene glycol monoethyl ether acetate, diethylene glycol monobutyl ether acetate, cyclohexanol acetate, propylene glycol diacetate, propylene glycol monomethyl ether acetate, propylene glycol monoethyl ether acetate (hereinafter referred to as PGMEA), dipropylene glycol methyl ether acetate, 3-methoxy-3-methyl-1-butyl acetate, 1,4-butanediol diacetate, 1,3-butylene glycol diacetate, and 1,6-hexanediol diacetate; ketones such as methyl ethyl ketone, cyclohexanone, 2-heptanone, and 3-heptanone; lactic acid alkyl esters such as methyl 2-hydroxypropionate and ethyl 2-hydroxypropionate; other esters such as ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate, and ethyl 2-oxobutanoate; aromatic hydrocarbons such as toluene and xylene; amides such as N-methylpyrrolidone, N,N-dimethylformamide, and N,N-dimethylacetamide; and alcohols such as butyl alcohol, isobutyl alcohol, pentanol, 4-methyl-2-pentanol, 3-methyl-2-butanol, 3-methyl-3-methoxybutanol, and diacetone alcohol.

In cases where a pigment is used as the coloring agent (F), an acetate compound is preferably used as the organic solvent from the viewpoint of dispersion stability of the pigment. The ratio of the acetate compound in the total content of organic solvents in the photosensitive resin composition of the present invention is preferably not less than 50% by mass, more preferably not less than 70% by mass. The content is preferably not more than 100% by mass, more preferably not more than 90% by mass.

Due to increases in the sizes of substrates, application using a die coating apparatus is becoming the mainstream. For realization of favorable volatility and drying characteristics in the application, an organic solvent prepared by mixing two or more compounds is preferably used. From the viewpoint of achieving a uniform film thickness of the photosensitive resin film of the photosensitive resin composition of the present invention, and also achieving favorable smoothness and stickiness of the surface, the ratio of compounds having a boiling point of 120 to 180° C. in the total organic solvents is preferably not less than 30% by mass. The content is preferably not more than 95% by mass.

The ratio of the organic solvent to the total solid content in the photosensitive resin composition of the present invention is preferably not less than 50 parts by mass, more preferably not less than 100 parts by mass with respect to 100 parts by mass of the total solid content. The ratio is preferably not more than 2,000 parts by mass, more preferably not more than 1,000 parts by mass.

The photosensitive resin composition of the present invention may contain an adhesion promoter. Examples of the adhesion promoter include silane coupling agents such as vinyltrimethoxysilane, vinyltriethoxysilane, epoxycyclohexylethyltrimethoxysilane, 3-glycidoxypropyltrimethoxysilane, 3-glycidoxypropyltriethoxysilane, p-styryltrimethoxysilane, 3-aminopropyltrimethoxysilane, 3-aminopropyltriethoxysilane, and N-phenyl-3-aminopropyltrimethoxysilane; titanium chelating agents; aluminum chelating agents; and compounds obtained by reacting an aromatic amine compound with an alkoxy-containing silicon compound. Two or more of these may be contained. By the inclusion of these adhesion promoters, adhesion properties to an underlying base material such as a silicon wafer, ITO, SiO₂, or silicon nitride can be improved during, for example, development of the photosensitive resin film. Further, resistance to oxygen plasma or UV ozone treatment employed for washing or the like can be increased. The content of the adhesion promoter is preferably not less than 0.1 parts by mass, more preferably not less than 0.3 parts by mass, with respect to 100 parts by mass of the alkali-soluble resin (A). The content is preferably not more than 10 parts by mass, more preferably not more than 5 parts by mass.

The photosensitive resin composition of the present invention may contain, if necessary, a surfactant for the purpose of improving wettability to the substrate. As the surfactant, a commercially available compound may be used. Specific examples of the surfactant include, but are not limited to, silicone-based surfactants such as the SH series, SD series, and ST series, manufactured by Dow Corning Toray Co., Ltd., the BYK series, manufactured by BYK-Chemie Japan K. K., the KP series, manufactured by Shin-Etsu Chemical Co., Ltd., and the TSF series, manufactured by GE Toshiba Silicone Co., Ltd.; fluorine-based surfactants such as the “MEGAFACE (registered trademark)” series, manufactured by DIC Corporation, the Fluorad series, manufacture by 3M Japan Limited, the “Surflon (registered trademark)” series and the “AsahiGuard (registered trademark)” series, manufactured by Asahi Glass Co., Ltd., and the PolyFox series, manufactured by OMNOVA Solutions Inc.; and surfactants containing an acrylic- and/or methacrylic-based polymer(s), such as the Polyflow series, manufactured by Kyoeisha Chemical Co., Ltd., and the “Disparlon (registered trademark)” series, manufactured by Kusumoto Chemicals, Ltd.

The content of the surfactant is preferably not less than 0.001 parts by mass, more preferably not less than 0.002 parts by mass, with respect to 100 parts by mass of the alkali-soluble resin (A). The content is preferably not more than 1 part by mass, more preferably not more than 0.5 parts by mass.

The method of producing the photosensitive resin composition of the present invention is described below. For example, by dissolving the components (A) to (E) and, if necessary, a radically polymerizable compound, coloring agent (F), dispersant, chain transfer agent, polymerization inhibitor, adhesion promoter, surfactant, and/or the like in an organic solvent, the photosensitive resin composition can be obtained. Examples of the method of dissolving these include stirring and heating. In cases of the heating, the heating temperature is preferably set within a range in which the performance of the resin composition is not deteriorated. The heating temperature is usually from room temperature to 80° C. The order of dissolving the components is not limited. For example, in one method, the compounds are dissolved in the order of increasing solubility. Surfactants, some adhesion promoters, and the like easily generate air bubbles during their dissolution by stirring. By adding these components after dissolution of other components, poor dissolution of the other components due to the generation of air bubbles can be prevented.

In cases where a pigment is used as the coloring agent, in one method, a disperser is used to disperse the pigment-containing coloring agent in a resin solution of the component (A).

Examples of the disperser include ball mills, bead mills, sand grinders, 3-roll mills, and high-speed impact mills. From the viewpoint of the dispersion efficiency and fine dispersion, bead mills are preferred. Examples of the bead mills include co-ball mills, basket mills, pin mills, and Dyno Mill. Examples of the beads for the bead mills include titania beads, zirconia beads, and zircon beads. The bead size for the bead mills is preferably not less than 0.01 mm, more preferably not less than 0.03 mm. The bead size is preferably not more than 5.0 mm, more preferably not more than 1.0 mm. In cases where the primary particle size of the coloring agent is small, and in cases where the particle size of the secondary particles formed by aggregation of the primary particles is small, the beads are preferably small beads having a size of 0.03 mm to 0.10 mm. In such cases, a bead mill including a centrifugation-based separator is preferred since it enables separation of small beads from the dispersion.

On the other hand, in cases where a coloring agent containing coarse particles having a near-submicron size is to be dispersed, beads having a size of not less than 0.10 mm are preferred for obtaining a sufficient pulverizing force.

The obtained resin composition is preferably filtered through a filtration filter to remove dust and particles. Examples of the filter pore size include, but are not limited to, 0.5 μm, 0.2 μm, 0.1 μm, and 0.05 μm. Examples of the material of the filtration filter include polypropylene (PP), polyethylene (PE), nylon (NY), and polytetrafluoroethylene (PTFE). The material is preferably polyethylene or nylon. In cases where the photosensitive resin composition contains a pigment, it is preferred to use a filtration filter having a pore size larger than the particle size of the pigment.

The method of producing a cured film of the present invention is described below in detail.

The method of producing a cured film of the present invention includes the steps of:

(1) applying the above-mentioned photosensitive resin composition to a substrate to form a photosensitive resin film;

(2) drying the photosensitive resin film;

(3) exposing the dried photosensitive resin film through a photomask;

(4) developing the exposed photosensitive resin film; and

(5) heat-treating the developed photosensitive resin film.

In the step of forming a photosensitive resin film, the photosensitive resin composition of the present invention is applied by the spin coating method, slit coating method, dip coating method, spray coating method, printing method, or the like to obtain a photosensitive resin film of the photosensitive resin composition. Prior to the application, the base material to which the photosensitive resin composition is to be applied may be pretreated with the above-mentioned adhesion promoter. Examples of the method therefor include a method in which the base material surface is treated using a solution prepared by dissolving the adhesion promoter at 0.5 to 20% by mass in a solvent such as isopropanol, ethanol, methanol, water, tetrahydrofuran, propylene glycol monomethyl ether acetate, propylene glycol monomethyl ether, ethyl lactate, or diethyl adipate. Examples of the method of treating the base material surface include spin coating, slit die coating, bar coating, dip coating, spray coating, and vapor treatment.

In the step of drying the photosensitive resin film, the photosensitive resin film after the application is subjected to drying treatment under reduced pressure as required, and then to heat treatment using a hot plate, an oven, infrared, or the like within the range of 50° C. to 180° C. for 1 minute to several hours, to obtain a photosensitive resin film.

The step of exposing the dried photosensitive resin film through a photomask is described below. Through a photomask having a desired pattern, an actinic ray is radiated onto the photosensitive resin film. The actinic ray used for the exposure may be ultraviolet, visible light, electron beam, X-ray, or the like. In the present invention, it is preferred to use the i-ray (365 nm), h-ray (405 nm), or g-ray (436 nm) of a mercury lamp. After the radiation of the actinic ray, post-exposure baking may be carried out. By performing the post-exposure baking, effects such as improvement of the resolution after the development and widening of the acceptable ranges of conditions of the development can be expected. The post-exposure baking may be carried out using an oven, hot plate, infrared, flash annealing apparatus, laser annealing apparatus, or the like. The post-exposure baking temperature is preferably 50 to 180° C., more preferably 60 to 150° C. The post-exposure baking time is preferably 10 seconds to several hours. In cases where the post-exposure baking time is within the range described above, the reaction proceeds well, and the development time can be reduced in some cases.

In the step of developing the exposed photosensitive resin film to allow pattern formation, the exposed photosensitive resin film is subjected to development using a developer, and the area other than the exposed area is removed. The developer is preferably an aqueous solution of an alkaline compound such as tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, or hexamethylenediamine. In some cases, the aqueous alkaline solution may further contain one of, or a combination of several of, polar solvents such as N-methyl-2-pyrrolidone, N,N-dimethylformamide, N,N-dimethylacetamide, dimethylsulfoxide, γ-butyrolactone, and dimethylacrylamide; alcohols such as methanol, ethanol, and isopropanol; esters such as ethyl lactate and propylene glycol monomethyl ether acetate; and ketones such as cyclopentanone, cyclohexanone, isobutyl ketone, and methylisobutyl ketone. Possible examples of the development method include the spraying method, paddling method, immersion method, and ultrasonic method.

The pattern formed by the development is then preferably subjected to rinsing treatment with distilled water. The distilled water to be used for performing the rinsing treatment may contain an alcohol such as ethanol or isopropyl alcohol; an ester such as ethyl lactate or propylene glycol monomethyl ether acetate; or the like.

Subsequently, the step of heat-treating the developed photosensitive resin film is carried out. Since the residual solvent and components having low heat resistance can be removed by the heat treatment, the heat resistance and the chemical resistance can be improved. In cases where the photosensitive resin composition of the present invention contains a polyimide precursor, polybenzoxazole precursor, and/or copolymer thereof, an imide ring or an oxazole ring can be formed by the heat treatment, so that the heat resistance and the chemical resistance can be improved. Further, in cases where the composition contains a thermal cross-linking agent, the thermal cross-linking reaction can be allowed to proceed by the heat treatment, so that the heat resistance and the chemical resistance can be improved. The heat treatment is carried out for 5 minutes to 5 hours by increasing the temperature in a stepwise manner at selected temperatures, or by continuously increasing the temperature within a selected temperature range. In one example, the heat treatment is carried out for 30 minutes at each of 150° C. and 250° C. Alternatively, for example, the temperature is linearly increased from room temperature to 300° C. for 2 hours. In the present invention, the heat treatment condition is preferably not less than 180° C., more preferably not less than 200° C., still more preferably not less than 230° C., especially preferably not less than 250° C. The heat treatment condition is preferably not more than 400° C., more preferably not more than 350° C., still more preferably not more than 300° C.

A method of producing a cured film using a photosensitive sheet prepared by forming the photosensitive resin composition of the present invention into a sheet shape is described below. The photosensitive sheet herein means a photosensitive resin composition having a sheet shape obtained by applying a photosensitive resin composition onto a strippable base material, and then drying the composition.

In cases where a photosensitive sheet obtained by forming the photosensitive resin composition of the present invention into a sheet shape is used, when the photosensitive sheet has a protection film, the protection film is peeled off. Thereafter, the photosensitive sheet and the substrate are disposed such that they face each other. They are then laminated on each other by heat pressing, to obtain a photosensitive resin film. The photosensitive sheet can be obtained by applying the photosensitive resin composition of the present invention to a support film composed of polyethylene terephthalate or the like, which is a strippable base material, and then drying the composition.

The heat pressing may be carried out by heat press treatment, thermal lamination treatment, thermal vacuum lamination treatment, or the like. The lamination temperature is preferably not less than 40° C. from the viewpoint of adhesion properties and embedding properties on the substrate. In cases where the photosensitive sheet has photosensitivity, the lamination temperature is preferably not more than 140° C. from the viewpoint of preventing curing of the photosensitive sheet during the lamination, which leads to a low resolution of the pattern formation in the exposure-development step.

With the photosensitive resin film obtained by lamination of the photosensitive sheet on a substrate, a cured film can be formed according to the above-described step of exposing the photosensitive resin film, step of developing the exposed photosensitive resin film, and step of performing heat curing.

The cured film formed with the photosensitive resin composition of the present invention can be used for a planarization layer and/or an insulation layer of a display device including a first electrode formed on a substrate, and a second electrode disposed such that it faces the first electrode, more specifically, a display device such as an LCD, ECD, ELD, or organic EL display device. An organic EL display device is described below as an example.

The organic EL display device of the present invention includes a driving circuit, a planarization layer, a first electrode, an insulation layer, an emitting layer, and a second electrode on a substrate, wherein the planarization layer and/or the insulation layer is/are composed of the cured film of the present invention. In a case of an active matrix display device, the device includes: a thin-film transistor (hereinafter referred to as TFT), and a wiring which is laterally positioned to the TFT and connected to the TFT, on a substrate such as a glass or a resin film; a planarization layer disposed thereon such that the layer covers irregularities; and a display element disposed on the planarization layer. The display element and the wiring are connected to each other through a contact hole formed in the planarization layer. In recent years, flexible organic EL display devices are becoming the mainstream. Therefore, in the organic EL display device, the substrate having the driving circuit is preferably composed of a resin film.

In the organic EL display device of the present invention, at least part of a portion including the cured film preferably includes a bendable portion and/or a portion fixed in a bent state. By using the cured film obtained by curing the photosensitive resin composition or the photosensitive resin sheet of the present invention, an organic EL display device having excellent bending resistance can be obtained. The bendable portion and/or the portion fixed in a bent state preferably has/have a curvature radius of 0.1 mm to 5 mm. In cases where the curvature radius is not less than 0.1 mm, bending resistance in the bending area can be secured. In cases where the curvature radius is not more than 5 mm, the device can have an excellent design by, for example, narrowing of a frame. The organic EL display device of the present invention can have an arbitrary appropriate bendable portion. For example, the organic EL display device may include a bendable central portion like a foldable display device, or may include a bendable end portion from the viewpoint of maximally securing an excellent design and the display area. The organic EL display device may be bendable along its longitudinal direction, or may be bendable along its transverse direction. The organic EL display device may include a specific bendable portion (such that, for example, part or all of the corners are bendable in an oblique direction(s)) depending on the intended use.

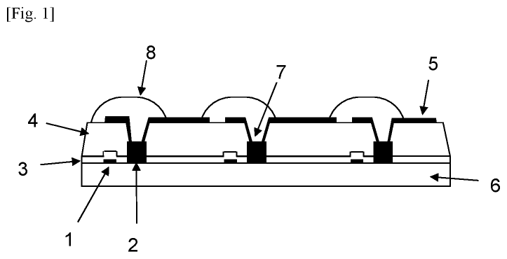

FIG. 1 illustrates a cross-sectional view of one example of a TFT substrate in which a planarization layer and an insulation layer are formed. On a substrate 6, bottom-gate or top-gate TFTs 1 are disposed such that they form a line thereon, and a TFT insulation layer 3 is formed such that the TFT insulation layer 3 covers the TFTs 1. Wirings 2 each connected to a TFT 1 are disposed on the TFT insulation layer 3. Further, a planarization layer 4 is disposed on the insulation layer 3 such that each wiring 2 is embedded in the planarization layer 4. Contact holes 7 reaching the wirings 2 are formed in the planarization layer 4. ITOs (transparent electrodes) 5 are formed on the planarization layer 4 such that the ITOs 5 are connected to the wirings 2 through the contact holes 7. Here, each ITO 5 acts as an electrode of a display element (for example, organic EL element). An insulation layer 8 is formed such that the periphery of the ITO 5 is covered therewith. The organic EL element may be a top-emission-type element, which releases emitted light from the side opposite to the substrate 6, or may be a bottom-emission-type element, which takes out light from the substrate 6 side. Thus, an active matrix organic EL display device including organic EL elements, to each of which a TFT 1 for driving it is connected, can be obtained.

The TFT insulation layer 3, the planarization layer 4, and/or the insulation layer 8 can be formed as described above by the step of forming a photosensitive resin film composed of the photosensitive resin composition or the photosensitive resin sheet of the present invention, the step of exposing the photosensitive resin film, the step of developing the exposed photosensitive resin film, and the step of heat-treating the developed photosensitive resin film. By a production method including these steps, an organic EL display device can be obtained.

The cured film formed with the photosensitive resin composition of the present invention may be used as an insulation film or a protection film constituting an electronic component. Here, examples of the electronic component include active components including a semiconductor, such as transistors, diodes, integrated circuits (hereinafter referred to as ICs), and memories; and passive components such as resistors, capacitors, and inductors. Electronic components using a semiconductor are also referred to as semiconductor devices. Preferred specific examples of the cured film in the electronic component include those used for a passivation film for a semiconductor; a surface protection film for a semiconductor element, TFT, or the like; an interlayer insulation film for a multilayer wiring in two to ten-layered high-density packaging; or an insulation film or a protection film for a touch screen display; or the like. Examples of the cured film are not limited thereto, and the cured film may have a variety of structures. The substrate surface for the formation of the cured film may be appropriately selected depending on the process.

Examples of the substrate surface include silicon, ceramics, metals, glasses, and epoxy resins. A plurality of these may be arranged on the same surface. Examples of the electronic devices including a surface protection film, interlayer insulation film, or the like in which the cured film of the present invention is arranged include MRAMs having low heat resistance. Thus, the cured film of the present invention is suitable for surface protection films of MRAMs. Further, new materials having lower heat resistance than those of conventional memories are likely to be used not only for MRAMs, but also for polymer ferroelectric RAMs (PFRAMs), Phase Change RAMs (PCRAMs), and Ovonics Unified Memories (OUMs), which are promising next-generation memories. Thus, the cured film of the present invention is also suitable for their surface protection films. Further, the cured film may be suitably used for a fan-out wafer-level package (hereinafter referred to as fan-out WLP). A fan-out WLP is a semiconductor package in which an expanded portion is provided in the vicinity of a semiconductor chip using a sealing resin such as an epoxy resin; redistributions are provided from electrodes on the semiconductor chip to the expanded portion; and solder balls are placed also on the expanded portion; to secure a required number of terminals. In a fan-out WLP, a wiring is disposed such that it is positioned over the boundary formed between the main surface of the semiconductor chip and the main surface of the sealing resin. Thus, an interlayer insulation film is formed on a base material constituted by two or more materials, that is, a semiconductor chip, which is provided with a metal wiring, and a sealing resin. A wiring is formed on the interlayer insulation film. Further, in a semiconductor package in which a semiconductor chip is embedded in a recess formed on a glass epoxy resin substrate, a wiring is disposed such that it is positioned over the boundary between the main surface of the semiconductor chip and the main surface of the printed board. Also in this mode, an interlayer insulation film is formed on a base material constituted by two or more materials, and a wiring is formed on the interlayer insulation film. The cured film obtained by curing of the photosensitive resin composition of the present invention is highly adhesive to semiconductor chips provided with a metal wiring, and also highly adhesive to sealing resins such as epoxy resins. Thus, the cured film can be preferably used as an interlayer insulation film to be provided on a base material constituted by two or more materials.

### EXAMPLES

The present invention is described below by way of Examples. However, the present invention is not limited by these Examples. Evaluation of the photosensitive resin compositions in Examples was carried out by the following methods.

### (1) Measurement of Average Molecular Weight

Regarding the molecular weight of each of the resins (P1) to (P4) used in Examples, the number average molecular weight (Mn) in terms of polystyrene was calculated by measurement using, as a GPC (gel permeation chromatography) apparatus, Waters 2690-996 (manufactured by Nihon Waters K.K.) with N-methyl-2-pyrrolidone (hereinafter referred to as NMP) as a developing solvent.

(2) Measurement of Film Thickness Using a surface roughness-profile analyzer (SURFCOM 1400D, manufactured by TOKYO SEIMITSU Co., Ltd.), the film thickness was measured after prebaking, after development, and after curing, at a measurement magnification of ×10,000, measurement length of 1.0 mm, and measurement speed of 0.30 mm/s.

### (3) Evaluation of Bending Resistance

The photosensitive resin composition of each Example was applied onto a polyimide film substrate by the spin coating method at an arbitrary rotation speed, to obtain a photosensitive resin film. A drying step was then carried out by prebaking on a hot plate at 120° C. for 2 minutes, to obtain a photosensitive resin film. Subsequently, shower development was carried out for 90 seconds with 2.38% by mass aqueous tetramethylammonium hydroxide solution using an automatic developing apparatus (AD-2000, manufactured by TAKIZAWA SANGYO K.K.), followed by rinsing with pure water for 30 seconds. The developed substrate having the photosensitive resin film thereon was cured for 60 minutes under a nitrogen atmosphere in an oven at 250° C. (heat treatment), to obtain a cured film having a film thickness of 2.0 μm.

Subsequently, the polyimide film substrate having the cured film was cut into 10 pieces each having a size of 50 mm (length)×10 mm (width). Subsequently, the polyimide film substrate was bent at 180° along the line at the 25-mm length such that the cured-film side faced the outside. The substrate was then kept in this state for 30 seconds. Thereafter, the bent polyimide film substrate was opened, and changes in the external appearance of the surface of the cured film were evaluated by observing the bending area along the line at the 25-mm length on the surface of the cured film using an FPD inspection microscope (MX-61L, manufactured by Olympus Corporation). The bending test was carried out at curvature radii within the range of 0.1 to 1.0 mm, and the minimum curvature radius without occurrence of changes in the external appearance such as detachment of the cured film from the polyimide film substrate or cracking on the surface of the cured film was recorded.

(4) Evaluation of Bending Resistance after High-Temperature Storage Test

A bending resistance test was carried out by the same method as in (3) except that, before the bending resistance test, a step of storing the polyimide film substrate having the cured film under an air atmosphere at 85° C. for 100 hours was added. The minimum curvature radius at which no change in the external appearance occurred was recorded.

### (5) Evaluation of Chemical Resistance

A cured film of the photosensitive resin composition was prepared by the same method as in (3) except that an OA-10 glass plate (manufactured by Nippon Electric Glass Co., Ltd.) was used instead of the polyimide film as the substrate. The cured film was subjected to immersion treatment in the stripping solution 106 manufactured by Tokyo Ohka Kogyo Co., Ltd. at 60° C. for 10 minutes. The film thickness was measured before and after this treatment, and the film loss due to the immersion treatment was calculated.

The compounds used in Examples and Comparative Examples are described below.

### Synthesis Example 1: Synthesis of Hydroxyl-Containing Diamine Compound

In 100 mL of acetone and 17.4 g (0.3 mol) of propylene oxide, 18.3 g (0.05 mol) of 2,2-bis(3-amino-4-hydroxyphenyl)hexafluoropropane (hereinafter referred to as BAHF) was dissolved, and the resulting solution was cooled to −15° C. To this solution, a solution of 20.4 g (0.11 mol) of 3-nitrobenzoyl chloride in 100 mL of acetone was added dropwise. Thereafter, the resulting mixture was allowed to react at −15° C. for 4 hours, and then allowed to warm to room temperature. A white solid, which precipitated as a result, was separated by filtration, and then dried under vacuum at 50° C.

After placing 30 g of the solid in a 300-mL stainless steel autoclave, the solid was dispersed in 250 mL of methyl cellosolve, and then 2 g of 5% palladium-carbon was added thereto. Hydrogen was introduced to the resulting mixture using a balloon, and reduction reaction was allowed to proceed at room temperature. About 2 hours later, the reaction was stopped after confirming that the balloon did not shrink any more. Thereafter, the reaction product was filtered to remove the palladium compound, which is a catalyst. The product was then concentrated using a rotary evaporator, to obtain the hydroxyl-containing diamine compound represented by the following formula.

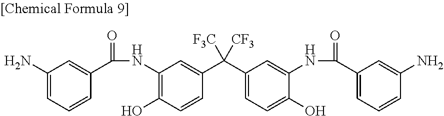 [SMILES: Nc1cccc(C(=O)Nc2cc(C(c3ccc(O)c(NC(=O)c4cccc(N)c4)c3)(C(F)(F)F)C(F)(F)F)ccc2O)c1]

### Synthesis Example 2: Synthesis of Alkali-Soluble Resin (P1)

Under a dry nitrogen gas flow, 62.0 g (0.20 mol) of 3,3′,4,4′-diphenyl ether tetracarboxylic dianhydride (hereinafter referred to as ODPA) was dissolved in 500 g of N-methyl-2-pyrrolidone (hereinafter referred to as NMP). To the resulting solution, 96.7 g (0.16 mol) of the hydroxyl-containing diamine compound obtained in Synthesis Example 1 was added together with 100 g of NMP, and the resulting mixture was allowed to react at 20° C. for 1 hour, and then at 50° C. for 2 hours. Subsequently, 8.7 g (0.08 mol) of 3-aminophenol as an end-capping agent was added thereto together with 50 g of NMP, and the resulting mixture was allowed to react at 50° C. for 2 hours. Thereafter, a solution prepared by diluting 47.7 g (0.40 mol) of N,N-dimethylformamide dimethylacetal with 100 g of NMP was added dropwise thereto for 10 minutes. Thereafter, the resulting mixture was stirred at 50° C. for 3 hours. Thereafter, the solution was allowed to cool to room temperature, and then poured into 5 L of water, to obtain a white precipitate. The precipitate was collected by filtration, washed three times with water, and then dried in a vacuum dryer at 80° C. for 24 hours, to obtain a polyimide precursor of interest (P1). The polyimide precursor (P1) had a number average molecular weight of 11,000.

### Synthesis Example 3: Synthesis of Alkali-Soluble Resin (P2)

Under a dry nitrogen gas flow, 58.6 g (0.16 mol) of BAHF, and 8.7 g (0.08 mol) of 3-aminophenol as an end-capping agent, were dissolved in 300 g of N-methyl-2-pyrrolidone (NMP). To the resulting solution, 62.0 g (0.20 mol) of ODPA was added together with 100 g of NMP, and the resulting mixture was stirred at 20° C. for 1 hour, and then at 50° C. for 4 hours. Thereafter, 15 g of xylene was added thereto, and the resulting mixture was stirred at 150° C. for 5 hours while allowing azeotropic distillation of water with the xylene. Thereafter, the solution was poured into 5 L of water, and a white precipitate was collected. The precipitate was collected by filtration, washed three times with water, and then dried in a vacuum dryer at 80° C. for 24 hours, to obtain a polyimide of interest (P2). The polyimide (P2) had a number average molecular weight of 8,200.

### Synthesis Example 4: Synthesis of Alkali-Soluble Resin (P3)

Under a dry nitrogen gas flow, 0.16 mol of a mixture of dicarboxylic acid derivatives obtained by reacting 41.3 g (0.16 mol) of diphenyl ether-4,4′-dicarboxylic acid with 43.2 g (0.32 mol) of 1-hydroxy-1,2,3-benzotriazole; and 73.3 g (0.20 mol) of BAHF; were dissolved in 570 g of NMP, and the resulting solution was allowed to react at 75° C. for 12 hours. Subsequently, a solution of 13.1 g (0.08 mol) of 5-norbornene-2,3-dicarboxylic anhydride in 70 g of NMP was added thereto. After stirring the resulting mixture for 12 hours, the reaction was stopped. The reaction mixture was filtered, and then poured into a solution of water/methanol=3/1 (volume ratio), to obtain a white precipitate. The precipitate was collected by filtration, washed three times with water, and then dried in a vacuum dryer at 80° C. for 24 hours, to obtain a polybenzoxazole (PBO) precursor of interest (P3). The PBO precursor (P3) had a number average molecular weight of 8,500.

### Synthesis Example 5: Synthesis of Alkali-Soluble Resin (P4)

By a known method (JP 3120476 B; Example 1), a methyl methacrylate/methacrylic acid/styrene copolymer (mass ratio, 30/40/30) was synthesized. To 100 parts by mass of the copolymer, 40 parts by mass of glycidyl methacrylate was added, and then reprecipitation with purified water, filtration, and drying were carried out to obtain an acrylic resin (P4) which is a polymer containing radically polymerizable monomers having a weight average molecular weight (Mw) of 15,000 and an acid number of 110 (mg KOH/g).

### Synthesis Example 6: Synthesis of Photo Acid Generator

Under a dry nitrogen gas flow, 21.22 g (0.05 mol) of TrisP-PA (trade name; manufactured by Honshu Chemical Industry Co., Ltd.) and 36.27 g (0.135 mol) of 5-naphthoquinone diazide sulfonyl acid chloride were dissolved in 450 g of 1,4-dioxane, and the resulting solution was left to stand to room temperature. To the solution, 15.18 g of triethylamine mixed with 50 g of 1,4-dioxane was added dropwise while the system was kept at less than 35° C. Thereafter, the resulting mixture was stirred at 30° C. for 2 hours. The resulting triethylamine salt was filtered, and the filtrate was poured into water. Thereafter, the resulting precipitate was collected by filtration. The precipitate was dried in a vacuum dryer, to obtain the photo acid generator 1 represented by the following formula.

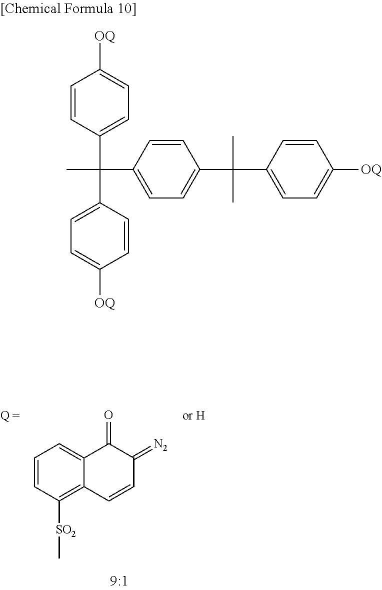

### <Thermal Cross-Linking Agent (C)>

HMOM-TPHAP: (the compound represented by the following chemical formula, having a phenolic hydroxyl group, and also having substituents having a molecular weight of not less than 40 at both ortho positions of the phenolic hydroxyl group, which compound is manufactured by Honshu Chemical Industry Co., Ltd.)

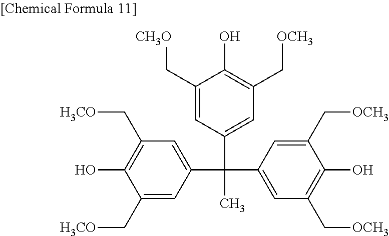

MX-270: “NIKALAC” (registered trademark) MX-270 (the compound represented by the following chemical formula; manufactured by Nippon Carbide Industries Co., Inc.)

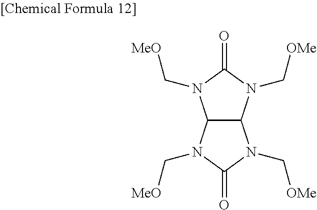 [SMILES: COCN1C(=O)N(COC)C2C1N(COC)C(=O)N2COC]

VG3101L: “TECHMORE” (registered trademark) VG3101L (the compound represented by the following chemical formula; manufactured by Printec Corporation).

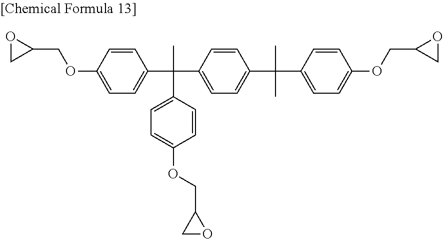 [SMILES: CC(C)(c1ccc(OCC2CO2)cc1)c1ccc(C(C)(c2ccc(OCC3CO3)cc2)c2ccc(OCC3CO3)cc2)cc1]

### <Phenolic Antioxidant (D)>

AO-60: “ADK STAB” (registered trademark) AO-60 (hindered phenol antioxidant; manufactured by ADEKA Corporation) (pKa=12.8 at 25° C.)

AO-80: “ADK STAB” (registered trademark) AO-80 (semi-hindered phenol antioxidant; manufactured by ADEKA Corporation) (pKa=12.0 at 25° C.)

AO-30: “ADK STAB” (registered trademark) AO-80 (less-hindered phenol antioxidant; manufactured by ADEKA Corporation) (pKa=11.6 at 25° C.)

### <Compound (E₁) Having Electron-Withdrawing Group and Phenolic Hydroxyl Group in Molecule, and Compound (E2) Having Phenolic Hydroxyl Group Indicating Acid Dissociation Constant pKa of 6.0 to 9.5 at 25° C.>

E(i): bisphenol AF (pKa=8.7 at 25° C.) E(ii): bisphenol S (pKa=7.6 at 25° C.)

E(iii): 4,4′-dihydroxybenzophenone (pKa=7.7 at 25° C.)

E(iv): 2,2′-dihydroxybenzophenone (pKa=7.3 at 25° C.) E(v): 4-(trifluoromethyl)phenol (pKa=8.5 at 25° C.)

### <Compound (E3) Having No Electron-Withdrawing Group, but Having Phenolic Hydroxyl Group in Molecule>

E(vi): 1,1,1-tris(4-hydroxyphenyl)ethane (pKa=10.0 at 25° C.)

### <Coloring Agent (F)>

Y201: C. I. Disperse Yellow 201 (yellow dye)

R18: C. I. Solvent Red 18 (red dye)

B63: C. I. Solvent Blue 63 (blue dye)

### <Solvent>

PGME: propylene glycol monomethyl ether

GBL: γ-butyrolactone

### Example 1

Under yellow light, 10.0 g of (P1) obtained in Synthesis Example 2 as the alkali-soluble resin (A), 2.0 g of the photo acid generator 1 obtained in Synthesis Example 1 as the photo acid generator (B), 2.0 g of HMOM-TPHAP as the thermal cross-linking agent (C), 0.5 g of AO-60 (acid dissociation constant pKa=12.8 at 25° C.) as the phenolic antioxidant (D), and 1.0 g of E(i) (acid dissociation constant pKa=8.7 at 25° C.) as the compound (E) having a phenolic hydroxyl group other than (D), were weighed and dissolved in 40.0 g of PGME and 10.0 g of GBL. Thereafter, the resulting solution was filtered through a filter having a pore size of 1 μm, to obtain a photosensitive resin composition. The (E₂/D) or (E₁/D) of this composition was 2. Using the photosensitive resin composition obtained, the evaluations (3) to (5) were carried out.

### Examples 2 to 5

The same composition as in Example 1 was used except that E(ii), E(iii), E(iv), or E(v) was used instead of E(i) in the same amount as E(i), as the compound (E) having a phenolic hydroxyl group other than (D).

### Examples 6 to 8

The same composition as in Example 1 was used except that the content of E(i) as the compound (E) having a phenolic hydroxyl group other than (D) was 3, 5, or 20 parts by mass.

### Example 9

The same composition as in Example 1 was used except that 10 parts by mass of E(vi) as the component (E3) was also used.

### Examples 10 and 11

The same composition as in Example 1 was used except that AO-80 (pKa=12.0 at 25° C.) or AO-30 (pKa=11.6 at 25° C.) was used instead of AO-60 in the same amount as AO-60, as the phenolic antioxidant (D).

### Examples 11 and 12

The same composition as in Example 1 was used except that MX-270 or VG3101L was used instead of HMOM-TPHAP in the same amount as HMOM-TPHAP, as the thermal cross-linking agent (C).

### Examples 14 to 16

The same composition as in Example 1 was used except that (P2) obtained in Synthesis Example 3, (P3) obtained in Synthesis Example 4, or (P4) obtained in Synthesis Example 5 was used instead of (P1) obtained in Synthesis Example 2 in the same amount as (P1), as the alkali-soluble resin (A).

### Examples 17 to 24

The same composition as in Example 1 was used except that the content of AO-60 as the phenolic antioxidant (D) was 1 part by mass instead of 5 parts by mass, and that 1, 2, 3, 5, 10, 15, 20, or 30 parts by mass of E(ii) was used instead of E(i), as the compound (E) having a phenolic hydroxyl group other than (D).

### Example 25

The same composition as in Example 1 was used except that 5 parts by mass of Y201, 5 parts by mass of R18, and 10 parts by mass of B63 as components of the coloring agent (F) were also used.

(E₂/D) or (E₁/D) of the composition obtained in each Example was as presented in Tables 1 to 4. Using each photosensitive resin composition obtained, the evaluations (3) to (5) were carried out.

### Comparative Examples 1 to 5

In Comparative Example 1, the same composition as in Example 1 was used except that no compound (E) having a phenolic hydroxyl group other than (D) was used. In Comparative Example 2, the same composition as in Example 1 was used except that 10 parts by mass of E(vi) was used as the component (E3) instead of the compound (E) having a phenolic hydroxyl group other than (D). In Comparative Example 3, the same composition as in Example 1 was used except that no phenolic antioxidant (D) was used. In Comparative Example 4, the same composition as in Example 1 was used except that no thermal cross-linking agent (C) was used. In Comparative Example 5, the same composition as in Example 25 was used except that no compound (E) having a phenolic hydroxyl group other than (D) was used.

(E₂/D) or (E₁/D) of each of these compositions was as presented in Tables 1 to 4. Using each photosensitive resin composition obtained, the evaluations (3) to (5) were carried out.

The compositions and the evaluation results for Examples and Comparative Examples are presented in Tables 1 to 4.

TABLE 1

| | | | | Example No. | | | |
|---|---|---|---|---|---|---|---|
| | | | | 1 | 2 | 3 | 4 |
| Photosensitive | Alkali-Soluble Resin (A) | | P1 (Polyimide Precursor | 100 | 100 | 100 | 100 |
| Resin | | | P2 (Polyimide) | | | | |
| Composition | | | P3 (PBO Precursor) | | | | |
| (parts by | | | P4 (Acrylic Resin) | | | | |
| mass) | Photo Acid Generator (B) | | Photo Acid Generator 1 | 20 | 20 | 20 | 20 |
| | Thermal Cross-Linking | | HMOM-TPHAP ^{Note 1)} | 20 | 20 | 20 | 20 |
| | Agent (C) | | MX-270 ^{Note 2)} | | | | |
| | | | VG3101L ^{Note 3)} | | | | |
| | Phenol | | AO-60 ^{Note 4)} (pKa: 12.8) | 5 | 5 | 5 | 5 |
| | Antioxidant (D) | | AO-80 ^{Note 5)} (pKa: 12.0) | | | | |
| | | | AO-30 ^{Note 6)} (pKa: 11.6) | | | | |
| | (E) Component | (E₁) and (E₂) | E(i) ^{Note 7)} (pKa: 8.7) | 10 | | | |
| | | | E(ii) ^{Note 8)} (pKa: 7.6) | | 10 | | |
| | | | E(iii) ^{Note 9)} (pKa: 7.7) | | | 10 | |
| | | | E(iv) ^{Note 10)} (pKa: 7.3) | | | | 10 |
| | | | E(v) ^{Note 11)} (pKa: 8.5) | | | | |
| | | (E₃) | E(vi) ^{Note 12)} (pKa: 10.0) | | | | |
| | (E₂/D) or (E₁/D) | | | 2 | 2 | 2 | 2 |
| | Solvent | | PGME ^{Note 13)} | 400 | 400 | 400 | 400 |
| | | | GBL ^{Note 14)} | 100 | 100 | 100 | 100 |
| Evaluation | Bending Resistance | | | 0.1 mm | 0.1 mm | 0.1 mm | 0.1 mm |
| Results | Bending Resistance after High Temperature Storage Test | | | 0.2 mm | 0.2 mm | 0.2 mm | 0.4 mm |
| | Chemical Resistance | | | 0.04 μm | 0.05 μm | 0.03 μm | 0.05 μm |
| | | | | Example No. | | | |
| | | | | 5 | 6 | 7 | 8 |
| Photosensitive | Alkali-Soluble Resin (A) | | P1 (Polyimide Precursor | 100 | 100 | 100 | 100 |
| Resin | | | P2 (Polyimide) | | | | |
| Composition | | | P3 (PBO Precursor) | | | | |
| (parts by | | | P4 (Acrylic Resin) | | | | |
| mass) | Photo Acid Generator (B) | | Photo Acid Generator 1 | 20 | 20 | 20 | 20 |
| | Thermal Cross-Linking | | HMOM-TPHAP ^{Note 1)} | 20 | 20 | 20 | 20 |
| | Agent (C) | | MX-270 ^{Note 2)} | | | | |
| | | | VG3101L ^{Note 3)} | | | | |
| | Phenol | | AO-60 ^{Note 4)} (pKa: 12.8) | 5 | 5 | 5 | 5 |
| | Antioxidant (D) | | AO-80 ^{Note 5)} (pKa: 12.0) | | | | |
| | | | AO-30 ^{Note 6)} (pKa: 11.6) | | | | |
| | (E) Component | (E₁) and (E₂) | E(i) ^{Note 7)} (pKa: 8.7) | | 3 | 5 | 20 |
| | | | E(ii) ^{Note 8)} (pKa: 7.6) | | | | |
| | | | E(iii) ^{Note 9)} (pKa: 7.7) | | | | |
| | | | E(iv) ^{Note 10)} (pKa: 7.3) | | | | |
| | | | E(v) ^{Note 11)} (pKa: 8.5) | 10 | | | |
| | | (E₃) | E(vi) ^{Note 12)} (pKa: 10.0) | | | | |

| (E₂/D) or (E₁/D) | | 2 | 0.6 | 1 | 4 |
|---|---|---|---|---|---|
| Solvent | PGME ^{Note 13)} | 400 | 400 | 400 | 400 |
| | GBL ^{Note 14)} | 100 | 100 | 100 | 100 |

| | | | | | |
|---|---|---|---|---|---|
| Evaluation | Bending Resistance | 0.1 mm | 0.2 mm | 0.1 mm | 0.1 mm |
| Results | Bending Resistance after High Temperature Storage Test | 0.3 mm | 0.6 mm | 0.4 mm | 0.2 mm |
| | Chemical Resistance | 0.17 μm | 0.03 μm | 0.04 μm | 0.08 μm |

^{Note 1)}
HMOM-TPHAP: Compound shown by [Chemical Formula 11], produced by Honshu Chemical Industry Co., Ltd.;
^{Note 2)}
MX-270: “NIKALAC” ® MX-270, Compound shown by [Chemical Formula 12], produced by Nippon Carbide Industries, Co. Inc.;
^{Note 3)}
VG3101L: “TECHMORE” ® VG3101L, Compound shown by [Chemical Formula 13], produced by PRINTEC INC.;
^{Note 4)}
AO-60: “ADKSTAB” ® AO-60, produced by ADEKA Corporation;
^{Note 5)}
AO-80: “ADKSTAB” ® AO-80, produced by ADEKA Corporation;
^{Note 6)}
AO-30: “ADKSTAB” ® AO-30, produced by ADEKA Corporation;
^{Note 7)}
E(i): Bisphenol AF;
^{Note 8)}
E(ii): Bisphenol S;
^{Note 9)}
E(iii): 4,4′-dihydroxy benzophenon;
^{Note 10)}
E(iv): 2,2′-dihydroxy benzophenon;
^{Note 11)}
E(v): 4-(trifluoromethyl)phenol;
^{Note 12)}
E(vi): 1,1,1-tris(4-hydroxyphenyl)ethane;
^{Note 13)}
PGME: Propylene glycol monomethyl ether;
^{Note 14)}
GBL: γ-butyrolactone

TABLE 2

| | | | | Example No. | | | |
|---|---|---|---|---|---|---|---|
| | | | | 9 | 10 | 11 | 12 |
| Photosensitive | Alkali-Soluble Resin (A) | | P1 (Polyimide Precursor) | 100 | 100 | 100 | 100 |
| Resin | | | P2 (Polyimide) | | | | |
| Composition | | | P3 (PBO Precursor) | | | | |
| (parts by | | | P4 (Acrylic Resin) | | | | |
| mass) | Photo Acid Generator (B) | | Photo Acid Generator 1 | 20 | 20 | 20 | 20 |
| | Thermal Cross-Linking | | HMOM-TPHAP ^{Note 1)} | 20 | 20 | 20 | |
| | Agent (C) | | MX-270 ^{Note 2)} | | | | 20 |
| | | | VG3101L ^{Note 3)} | | | | |
| | Phenol Antioxidant (D) | | AO-60 ^{Note 4)} (pKa: 12.8) | 5 | | | 5 |
| | | | AO-80 ^{Note 5)} (pKa: 12.0) | | 5 | | |
| | | | AO-30 ^{Note 6)} (pKa: 11.6) | | | 5 | |
| | (E) Component | (E₁) and (E₂) | E(i) ^{Note 7)} (pKa: 8.7) | 10 | 10 | 10 | 10 |
| | | | E(ii) ^{Note 8)} (pKa: 7.6) | | | | |
| | | | E(iii) ^{Note 9)} (pKa: 7.7) | | | | |
| | | | E(iv) ^{Note 10)} (pKa: 7.3) | | | | |
| | | | E(v) ^{Note 11)} (pKa: 8.5) | | | | |
| | | (E₃) | E(vi) ^{Note 12)} (pKa: 10.0) | 10 | | | |
| | (E₂/D) or (E₁/D) | | | 2 | 2 | 2 | 2 |
| | Solvent | | PGME ^{Note 13)} | 400 | 400 | 400 | 400 |
| | | | GBL ^{Note 14)} | 100 | 100 | 100 | 100 |
| Evaluation | Bending Resistance | | | 0.1 mm | 0.1 mm | 0.1 mm | 0.2 mm |
| Results | Bending Resistance after High Temperature Storage Test | | | 0.2 mm | 0.3 mm | 0.5 mm | 0.4 mm |
| | Chemical Resistance | | | 0.08 μm | 0.05 μm | 0.05 μm | 0.08 μm |
| | | | | Example No. | | | |
| | | | | 13 | 14 | 15 | 16 |
| Photosensitive | Alkali-Soluble Resin (A) | | P1 (Polyimide Precursor) | 100 | | | |
| Resin | | | P2 (Polyimide) | | 100 | | |
| Composition | | | P3 (PBO Precursor) | | | 100 | |
| (parts by | | | P4 (Acrylic Resin) | | | | 100 |
| mass) | Photo Acid Generator (B) | | Photo Acid Generator 1 | 20 | 20 | 20 | 20 |
| | Thermal Cross-Linking | | HMOM-TPHAP ^{Note 1)} | | 20 | 20 | 20 |
| | Agent (C) | | MX-270 ^{Note 2)} | | | | |
| | | | VG3101L ^{Note 3)} | 20 | | | |
| | Phenol Antioxidant (D) | | AO-60 ^{Note 4)} (pKa: 12.8) | 5 | 5 | 5 | 5 |
| | | | AO-80 ^{Note 5)} (pKa: 12.0) | | | | |
| | | | AO-30 ^{Note 6)} (pKa: 11.6) | | | | |
| | (E) Component | (E₁) and (E₂) | E(i) ^{Note 7)} (pKa: 8.7) | 10 | 10 | 10 | 10 |
| | | | E(ii) ^{Note 8)} (pKa: 7.6) | | | | |
| | | | E(iii) ^{Note 9)} (pKa: 7.7) | | | | |
| | | | E(iv) ^{Note 10)} (pKa: 7.3) | | | | |
| | | | E(v) ^{Note 11)} (pKa: 8.5) | | | | |
| | | (E₃) | E(vi) ^{Note 12)} (pKa: 10.0) | | | | |

| (E₂/D) or (E₁/D) | | 2 | 2 | 2 | 2 |
|---|---|---|---|---|---|
| Solvent | PGME ^{Note 13)} | 400 | 400 | 400 | 400 |
| | GBL ^{Note 14)} | 100 | 100 | 100 | 100 |

| | | | | | |
|---|---|---|---|---|---|
| Evaluation | Bending Resistance | 0.2 mm | 0.1 mm | 0.1 mm | 0.3 mm |
| Results | Bending Resistance after High Temperature Storage Test | 0.4 mm | 0.2 mm | 0.2 mm | 0.6 mm |
| | Chemical Resistance | 0.14 μm | 0.10 μm | 0.08 μm | 0.07 μm |

^{Note 1)}
HMOM-TPHAP: Compound shown by [Chemical Formula 11], produced by Honshu Chemical Industry Co., Ltd.;
^{Note 2)}
MX-270: “NIKALAC” ® MX-270, Compound shown by [Chemical Formula 12], produced by Nippon Carbide Industries, Co. Inc.;
^{Note 3)}
VG3101L: “TECHMORE” ® VG3101L, Compound shown by [Chemical Formula 13], produced by PRINTEC INC.;
^{Note 4)}
AO-60: “ADKSTAB” ® AO-60, produced by ADEKA Corporation;
^{Note 5)}
AO-80: “ADKSTAB” ® AO-80, produced by ADEKA Corporation;
^{Note 6)}
AO-30: “ADKSTAB” ® AO-30, produced by ADEKA Corporation;
^{Note 7)}
E(i): Bisphenol AF;
^{Note 8)}
E(ii): Bisphenol S;
^{Note 9)}
E(iii): 4,4′-dihydroxy benzophenon;
^{Note 10)}
E(iv): 2,2′-dihydroxy benzophenon;
^{Note 11)}
E(v): 4-(trifluoromethyl)phenol;
^{Note 12)}
E(vi): 1,1,1-tris(4-hydroxyphenyl)ethane;
^{Note 13)}
PGME: Propylene glycol monomethyl ether;
^{Note 14)}
GBL: γ-butyrolactone

TABLE 3

| | | | | Example No. | | | |
|---|---|---|---|---|---|---|---|
| | | | | 17 | 18 | 19 | 20 |
| Photosensitive | Alkali-Soluble Resin (A) | | P1 (Polyimide Precursor) | 100 | 100 | 100 | 100 |
| Resin | | | P2 (Polyimide) | | | | |
| Composition | | | P3 (PBO Precursor) | | | | |
| (parts by | | | P4 (Acrylic Resin) | | | | |
| mass) | Photo Acid Generator (B) | | Photo Acid Generator 1 | 20 | 20 | 20 | 20 |
| | Thermal Cross-Linking | | HMOM-TPHAP ^{Note 1)} | 20 | 20 | 20 | 20 |
| | Agent (C) | | MX-270 ^{Note 2)} | | | | |
| | | | VG3101L ^{Note 3)} | | | | |
| | Phenol Antioxidant (D) | | AO-60 ^{Note 4)} (pKa: 12.8) | 1 | 1 | 1 | 1 |
| | | | AO-80 ^{Note 5)} (pKa: 12.0) | | | | |
| | | | AO-30 ^{Note 6)} (pKa: 11.6) | | | | |
| | (E) Component | (E₁) and (E₂) | E(i) ^{Note 7)} (pKa: 8.7) | | | | |
| | | | E(ii) ^{Note 8)} (pKa: 7.6) | 1 | 2 | 3 | 5 |
| | | | E(iii) ^{Note 9)} (pKa: 7.7) | | | | |
| | | | E(iv) ^{Note 10)} (pKa: 7.3) | | | | |
| | | | E(v) ^{Note 11)} (pKa: 8.5) | | | | |
| | | (E₃) | E(vi) ^{Note 12)} (pKa: 10.0) | | | | |
| | (E₂/D) or (E₁/D) | | | 1 | 2 | 3 | 5 |
| | Solvent | | PGME ^{Note 13)} | 400 | 400 | 400 | 400 |
| | | | GBL ^{Note 14)} | 100 | 100 | 100 | 100 |
| Evaluation | Bending Resistance | | | 0.1 mm | 0.1 mm | 0.1 mm | 0.1 mm |
| Results | Bending Resistance after High Temperature Storage Test | | | 0.8 mm | 0.5 mm | 0.4 mm | 0.3 mm |
| | Chemical Resistance | | | 0.03 μm | 0.04 μm | 0.04 μm | 0.05 μm |
| | | | | Example No. | | | |
| | | | | 21 | 22 | 23 | 24 |
| Photosensitive | Alkali-Soluble Resin (A) | | P1 (Polyimide Precursor) | 100 | 100 | 100 | 100 |
| Resin | | | P2 (Polyimide) | | | | |
| Composition | | | P3 (PBO Precursor) | | | | |
| (parts by | | | P4 (Acrylic Resin) | | | | |
| mass) | Photo Acid Generator (B) | | Photo Acid Generator 1 | 20 | 20 | 20 | 20 |
| | Thermal Cross-Linking | | HMOM-TPHAP ^{Note 1)} | 20 | 20 | 20 | 20 |
| | Agent (C) | | MX-270 ^{Note 2)} | | | | |
| | | | VG3101L ^{Note 3)} | | | | |
| | Phenol Antioxidant (D) | | AO-60 ^{Note 4)} (pKa: 12.8) | 1 | 1 | 1 | 1 |
| | | | AO-80 ^{Note 5)} (pKa: 12.0) | | | | |
| | | | AO-30 ^{Note 6)} (pKa: 11.6) | | | | |
| | (E) Component | (E₁) and (E₂) | E(i) ^{Note 7)} (pKa: 8.7) | | | | |
| | | | E(ii) ^{Note 8)} (pKa: 7.6) | 10 | 15 | 20 | 30 |
| | | | E(iii) ^{Note 9)} (pKa: 7.7) | | | | |
| | | | E(iv) ^{Note 10)} (pKa: 7.3) | | | | |
| | | | E(v) ^{Note 11)} (pKa: 8.5) | | | | |
| | | (E₃) | E(vi) ^{Note 12)} (pKa: 10.0) | | | | |

| (E₂/D) or (E₁/D) | | 10 | 15 | 20 | 30 |
|---|---|---|---|---|---|
| Solvent | PGME ^{Note 13)} | 400 | 400 | 400 | 400 |
| | GBL ^{Note 14)} | 100 | 100 | 100 | 100 |

| | | | | | |
|---|---|---|---|---|---|
| Evaluation | Bending Resistance | 0.1 mm | 0.1 mm | 0.1 mm | 0.1 mm |
| Results | Bending Resistance after High Temperature Storage Test | 0.3 mm | 0.3 mm | 0.3 mm | 0.3 mm |
| | Chemical Resistance | 0.07 μm | 0.13 μm | 0.23 μm | 0.39 μm |

^{Note 1)}
HMOM-TPHAP: Compound shown by [Chemical Formula 11], Honshu Chemical Industry Co., Ltd.;
^{Note 2)}
MX-270: “NIKALAC” ® MX-270, Compound shown by [Chemical Formula 12], produced by Nippon Carbide Industries, Co. Inc.;
^{Note 3)}
VG3101L: “TECHMORE” ® VG3101L, Compound shown by [Chemical Formula 13], produced by PRINTEC INC.;
^{Note 4)}
AO-60: “ADKSTAB” ® AO-60, produced by ADEKA Corporation;
^{Note 5)}
AO-80: “ADKSTAB” ® AO-80, produced by ADEKA Corporation;
^{Note 6)}
AO-30: “ADKSTAB” ® AO-30, produced by ADEKA Corporation;
^{Note 7)}
E(i): Bisphenol AF;
^{Note 8)}
E(ii): Bisphenol S;
^{Note 9)}
E(iii): 4,4′-Bisphenol;
^{Note 10)}
E(iv): 2,2′-dihydroxy benzophenon;
^{Note 11)}
E(v): 4-(trifluoromethyl)phenol;
^{Note 12)}
E(vi): 1,1,1-tris(4-hydroxyphenyl)ethane;
^{Note 13)}
PGME: Propylene glycol monomethyl ether;
^{Note 14)}
GBL: γ-butyrolactone

TABLE 4

| | | | | Example | | | | | |
|---|---|---|---|---|---|---|---|---|---|
| | | | | No. | Comparative Example No. | | | | |
| | | | | 25 | 1 | 2 | 3 | 4 | 5 |
| Photosensitive | Alkali-Soluble Resin (A) | | P1 (Polyimide Precursor) | 100 | 100 | 100 | 100 | 100 | 100 |
| Resin | | | P2 (Polyimide) | | | | | | |
| Composition | | | P3 (PBO Precursor) | | | | | | |
| (parts by | | | P4 (Acrylic Resin) | | | | | | |
| mass) | Photo Acid Generator (B) | | Photo Acid Generator 1 | 20 | 20 | 20 | 20 | 20 | 20 |
| | Thermal Cross-Linking | | HMOM-TPHAP ^{Note 1)} | 20 | 20 | 20 | 20 | | 20 |
| | Agent (C) | | MX-270 ^{Note 2)} | | | | | | |
| | | | VG3101L ^{Note 3)} | | | | | | |
| | Phenol Antioxidant (D) | | AO-60 ^{Note 4)} (pKa: 12.8) | 5 | 5 | 5 | | 5 | 5 |
| | | | AO-80 ^{Note 5)} (pKa: 12.0) | | | | | | |
| | | | AO-30 ^{Note 6)} (pKa: 11.6) | | | | | | |
| | (E) Component | (E₁) and (E₂) | E(i) ^{Note 7)} (pKa: 8.7) | 10 | | | 10 | 10 | |
| | | | E(ii) ^{Note 8)} (pKa: 7.6) | | | | | | |
| | | | E(iii) ^{Note 9)} (pKa: 7.7) | | | | | | |
| | | | E(iv) ^{Note 10)} (pKa: 7.3) | | | | | | |
| | | | E(v) ^{Note 11)} (pKa: 8.5) | | | | | | |
| | | (E₃) | E(vi) ^{Note 12)} (pKa: 10.0) | | | 10 | | | |

| (E₂/D) or (E₁/D) | | 2 | 0 | 0 | — | 2 | 0 |
|---|---|---|---|---|---|---|---|
| (F) Component | Y201 ^{Note 13)} | 5 | | | | | 5 |
| | R18 ^{Note 14)} | 5 | | | | | 5 |
| | B63 ^{Note 15)} | 10 | | | | | 10 |
| Solvent | PGME ^{Note 16)} | 400 | 400 | 400 | 400 | 400 | 400 |
| | GBL ^{Note 17)} | 100 | 100 | 100 | 100 | 100 | 100 |

| | | | | | | | |
|---|---|---|---|---|---|---|---|
| Evaluation | Bending Resistance | 0.1 mm | 0.2 mm | 0.2 mm | 0.5 mm | 0.8 mm | 0.3 mm |
| Results | Bending Resistance after High Temperature Storage Test | 0.2 mm | — | 1.0 mm | — | — | — |
| | Chemical Resistance | 0.07 μm | 0.03 μm | 0.07 μm | 0.10 μm | 1.55 μm | 0.05 μm |

^{Note 1)}
HMOM-TPHAP: Compound shown by [Chemical Formula 11], Honshu Chemical Industry Co., Ltd.;
^{Note 2)}
MX-270: “NIKALAC” ® MX-270, Compound shown by [Chemical Formula 12], produced by Nippon Carbide Industries, Co. Inc.;
^{Note 3)}
VG3101L: “TECHMORE” ® VG3101L, Compound shown by [Chemical Formula 13], produced by PRINTEC INC.;
^{Note 4)}
AO-60: “ADKSTAB” ® AO-60, produced by ADEKA Corporation;
^{Note 5)}
AO-80: “ADKSTAB” ® AO-80, produced by ADEKA Corporation;
^{Note 6)}
AO-30: “ADKSTAB” ® AO-30, produced by ADEKA Corporation;
^{Note 7)}
E(i): Bisphenol AF;
^{Note 8)}
E(ii): Bisphenol S;
^{Note 9)}
E(iii): 4,4′-dihydroxy benzophenon;
^{Note 10)}
E(iv): 2,2′-dihydroxybenzophenon;
^{Note 11)}
E(v): 4-(trifluoromethyl)phenol;
^{Note 12)}
E(vi): 1,1,1-tris(4-hydroxyphenyl)ethane;
^{Note 13)}
Y201: C.I.Disperse Yellow 201;
^{Note 14)}
R18: C.I.Solvent Red 18;
^{Note 15)}
B63: C.I.Solvent Blue 63;
^{Note 16)}
PGME: Propylene glycol monomethyl ether;
^{Note 17)}
GBL: y-butyrolactone;
^{Note 18)}
“—” means that cracks were generated at all conditions.

In each of Examples 1 to 25, good results were obtained for all of the bending resistance, the bending resistance after the high-temperature storage test, and the chemical resistance. In contrast, in each of Comparative Example 1, Comparative Example 2, and Comparative Example 5, wherein neither the component (E₁) nor the component (E₂) was used, Comparative Example 3, wherein the component (D) was not used, and Comparative Example 4, wherein the component (C) was not used, poor results were obtained for the bending resistance, and the bending resistance after the high-temperature storage test.

In each of Example 1, Example 14, and Example 15, wherein a polyimide, polyimide precursor, or polybenzoxazole precursor, respectively, was used as the component (A), better results were obtained for the bending resistance, and the bending resistance after the high-temperature storage test, compared to Example 16, wherein an acrylic resin was used.

In Example 1, wherein HMOM-TPHAP, which is a thermal cross-linking agent having a phenolic hydroxyl group, and also having a methylol group and/or an alkoxymethyl group at both ortho positions of the phenolic hydroxyl group, was used as the component (C), better results were obtained for all of the bending resistance, the bending resistance after the high-temperature storage test, and the chemical resistance, compared to Example 12 and Example 13, wherein other thermal cross-linking agents were used.

In Example 1, wherein AO-60, which is a hindered phenol antioxidant, was used as the component (D), a better result was obtained for the bending resistance after the high-temperature storage test, compared to Example 10 and Example 11, wherein other phenolic antioxidants were used.

In each of Examples 1 to 4, wherein a compound having two or more phenolic hydroxyl groups in the molecule was used as the component (E₁) or (E₂), a better result was obtained for the chemical resistance, compared to Example 5, wherein a compound having one phenolic hydroxyl group in the molecule was used. In each of Example 1, Example 2, Example 3, and Example 5, wherein a compound having hydrogen atoms at both ortho positions of a phenolic hydroxyl group was used as the component (E₁) or (E₂), a better result was obtained for the bending resistance after the high-temperature storage test, compared to Example 4, wherein a group other than a hydroxyl group is contained at an ortho position of a phenolic hydroxyl group.

### DESCRIPTION OF SYMBOLS

1: TFT
2: Wiring
3: TFT insulation film
4: Planarization layer
5: Electrode
6: Substrate
7: Contact hole
8: Insulation layer

### INDUSTRIAL APPLICABILITY

The cured film formed with the photosensitive resin composition of the present invention can be used for a planarization layer and/or an insulation layer of a display device including a first electrode formed on a substrate, and a second electrode disposed such that it faces the first electrode, more specifically, a display device such as an LCD, ECD, ELD, or organic EL display device. The cured film can be used also as an insulation film or a protection film constituting an electronic component. Here, examples of the electronic component include active components including a semiconductor, such as transistors, diodes, ICs, and memories; and passive components such as resistors, capacitors, and inductors. Electronic components using a semiconductor are also referred to as semiconductor devices. Preferred specific examples of the cured film in the electronic component include those used for a passivation film for a semiconductor; a surface protection film for a semiconductor element, TFT, or the like; an interlayer insulation film for a multilayer wiring in two- to ten-layered high-density packaging; an insulation film or a protection film for a touch screen display; an insulation layer for an organic electroluminescent element; or the like. Examples of the cured film are not limited thereto, and the cured film may have a variety of structures. The photosensitive resin composition of the present invention can also be preferably used for a fan-out WLP.

1. A photosensitive resin composition comprising:
an alkali-soluble resin (A);
a photo acid generator (B);
a thermal cross-linking agent (C);
a phenolic antioxidant (D); and
a compound (E₂) having a phenolic hydroxyl group indicating an acid dissociation constant pKa of 6.0 to 9.5 at 25° C.

2. The photosensitive resin composition according to claim 1, wherein the phenolic antioxidant (D) has a phenolic hydroxyl group indicating an acid dissociation constant pKa of 10.1 to 13.0 at 25° C.

3. The photosensitive resin composition according to claim 1, wherein the mass ratio between the content of the phenolic antioxidant (D) and the content of the compound (E₂) having a phenolic hydroxyl group indicating an acid dissociation constant pKa of 6.0 to 9.5 at 25° C. (E₂/D) is 2 to 20.

4. A photosensitive resin composition comprising:
an alkali-soluble resin (A);
a photo acid generator (B);
a thermal cross-linking agent (C);
a phenolic antioxidant (D); and
a compound (E) having a phenolic hydroxyl group other than (D);
wherein the compound (E) having a phenolic hydroxyl group other than (D) contains a compound (E₁) having an electron-withdrawing group and a phenolic hydroxyl group in the molecule.

5. The photosensitive resin composition according to claim 4, wherein the mass ratio of the content of the compound (E₁) having an electron-withdrawing group and a phenolic hydroxyl group in the molecule (E₁/D) is 2 to 20.

6. The photosensitive resin composition according to claim 1, wherein the alkali-soluble resin (A) contains a polyimide, polyimide precursor, polybenzoxazole precursor, and/or copolymer thereof.

7. The photosensitive resin composition according to claim 1, wherein the phenolic antioxidant (D) contains a hindered phenol antioxidant.

8. The photosensitive resin composition according to claim 1, for use in formation of an insulation film of an organic EL display device including a bendable portion and/or a portion fixed in a bent state.

9. The photosensitive resin composition according to claim 1, wherein the thermal cross-linking agent (C) contains a thermal cross-linking agent having a phenolic hydroxyl group, and also having a methylol group and/or an alkoxymethyl group at both ortho positions of the phenolic hydroxyl group.

10. The photosensitive resin composition according to claim 1, further comprising a coloring agent (F).

11. The photosensitive resin composition according to claim 1, wherein the photosensitive resin composition has a sheet shape.

12. A cured film comprising a cured product of the photosensitive resin composition according to claim 1.

13. An element comprising the cured film according to claim 12.

14. An organic EL display device comprising the cured film according to claim 12.

15. The organic EL display device according to claim 14, wherein at least part of a portion comprising the cured film of the organic EL display device includes a bendable portion and/or a portion fixed in a bent state, the bendable portion and/or the portion fixed in a bent state having a curvature radius within the range of 0.1 mm to 5 mm

16. An electronic component comprising the cured film according to claim 12, the cured film being disposed as an interlayer insulation film between redistributions

17. A method of producing a cured film, the method comprising the steps of:
(1) applying the photosensitive resin composition according to claim 1 to a substrate to form a photosensitive resin film;
(2) drying the photosensitive resin film;
(3) exposing the dried photosensitive resin film through a photomask;
(4) developing the exposed photosensitive resin film; and
(5) heat-treating the developed photosensitive resin film.

18. A method of producing an organic EL display device, the method comprising the step of forming a cured film by the method according to claim 17.

19. The photosensitive resin composition according to claim 2, wherein the mass ratio between the content of the phenolic antioxidant (D) and the content of the compound (E₂) having a phenolic hydroxyl group indicating an acid dissociation constant pKa of 6.0 to 9.5 at 25° C. (E₂/D) is 2 to 20.

20. The photosensitive resin composition according to claim 2, wherein the alkali-soluble resin (A) contains a polyimide, polyimide precursor, polybenzoxazole precursor, and/or copolymer thereof.
